(19) United States
(12) Patent Application Publication
(10) Pub. No.: US 2026/0119754 A1
(43) Pub. Date: Apr. 30, 2026

(54) DYNAMIC AGENT-BASED MODELING FOR LANGUAGE MODEL-BASED ARTIFICIAL INTELLIGENCE AGENTS

(71) Applicant: QpiAI India Private Limited, Bangalore (IN)

(72) Inventors: Aswanth Krishnan, Bengaluru (IN); Lakshya Priyadarshi, Lucknow (IN); Sachin Kumar, Bengaluru (IN); Nagendra Nagaraja, Bangalore (IN)

(73) Assignee: QpiAI India Private Limited, Bangalore (IN)

(21) Appl. No.: 19/326,403

(22) Filed: Sep. 11, 2025

(30) Foreign Application Priority Data
Oct. 30, 2024 (IN) 202441083002

(51) Int. Cl. G06F 30/27; G06N 5/022

(52) U.S. Cl. CPC G06F 30/27; G06N 5/022; G06F 16/243; G06F 40/30

(57) ABSTRACT

An artificial intelligence (AI) agent is configured to automatically generate agent-based model simulations based on the tasks. The AI agent receives an inbound task representing a hypothesis or other question indicating a use for an agent-based model. The AI agent selects from a plurality of model agents for the simulation. Model agent selection may include a semantic comparison between metadata for a number of candidate agents and the inbound task. The AI agent can execute the simulation and determine other scenarios to investigate in order to enhance its response. The AI agent can perform a number of actions responsive to the inbound task that depend on the results of the simulations. The AI agent may update a user interface or generate a notification with a recommendation based on the results. The AI agent may interact with an API to effect a change in a physical system represented by the model.

### CROSS-REFERENCE TO RELATED PATENT APPLICATIONS

This application claims the benefit of priority to Indian Provisional Patent Application No. 202441083002, filed Oct. 30, 2024, the entire contents of which are herein incorporated by reference.

### BACKGROUND

Artificial intelligence (AI) or language model (LM)-based agents can be employed to respond to various types of prompts and input tasks. LM-based agents can take multiple actions including generating a text response to a prompt, generating notifications, or interacting with application programming interfaces (APIs) to cause effects in external systems. LM-based agents can generate inaccurate results when responding to a prompt for which the agent has no prior experience.

### BRIEF DESCRIPTION OF THE DRAWINGS

The accompanying drawings are not intended to be drawn to scale. Like reference numbers and designations in the various drawings indicate like elements. For purposes of clarity, not every component may be labeled in every drawing. In the drawings:

FIG. 1 is a block diagram illustrating an example system for operating artificial intelligence (AI) agents enhanced with dynamic agent-based modeling (ABM) capability, according to some embodiments;

FIG. 2A is a block diagram illustrating example hardware devices suitable for implementing at least a portion of the system of FIG. 1, according to some embodiments;

FIG. 2B is a block diagram illustrating an example architecture suitable for implementing at least a portion of the system of FIG. 1, according to some embodiments;

FIG. 3 is a block diagram of an ABM enhanced AI agent of FIG. 1, according to some embodiments;

FIG. 4A is a data flow diagram illustrating data flow within an ABM enhanced AI agent, according to some embodiments;

FIG. 4B is a flow diagram illustrating an operational flow to allocate hardware resources for an ABM, according to some embodiments;

FIG. 4C is a flow diagram illustrating an operational flow to execute an ABM simulation, according to some embodiments;

FIG. 4D is flow diagrams illustrating an operational flow to generate insight based on ABM simulations, according to some embodiments; and

FIG. 5 is a flow of operations for responding to an input task with a language model using an automatically generated ABM, according to some embodiments.

### DETAILED DESCRIPTION

Below are detailed descriptions of various concepts related to, and approaches, methods, apparatuses, and systems for implementing the various techniques described herein. The various concepts introduced above and discussed in greater detail below may be implemented in any of numerous ways, as the described concepts are not limited to any particular manner of implementation. Examples of specific implementations and applications are provided primarily for illustrative purposes.

Language models (e.g. large language models such as generative pretrained transformer models, bidirectional encoder representations from transformers, etc. ; small language models; multimodal language models, etc.) can be used in several applications including summarizing documents, extracting information, and generating computer code. Language models can be integrated within artificial intelligence (AI) agents to automate several tasks. For example, AI agents can monitor systems for security threats and automatically take mitigating actions including generating notifications, blocking transactions, and detecting exploited vulnerabilities. AI agents can be used to simulate characters in games and/or handle customer service calls. However, language models and AI agents based on language models can produce inaccurate results and take inappropriate actions when prompted with queries related to information for which few or no examples were provided in their training data and no examples were provided in the prompt. The inaccurate results, often called hallucinations due to their ability to appear legitimate without further investigation, can cause detrimental effects. For example, language models may generate nonworking code and/or code with security vulnerabilities.

The problem of hallucinations and/or other inaccuracies is amplified when language models or AI agents are asked to support users in analysis or optimization of complex, dynamic environments. Traditional language models and agents may not be trained with data from such systems. Further, the language models and AI agents may also lack flexibility to adapt to rapidly changing contexts and/or have context windows that are not amenable to analysis of complex systems. Without examples at a particular state within the dynamic environment or system, language models may output information and recommendations for different states or system configurations. It may be impossible to implement such recommendations, or worse, if the recommendation can be implemented, it may lead to suboptimal or even deleterious effects.

Systems and methods described herein address the technical problems of hallucinations and inaccuracies of language models and AI agents when applied to complex, dynamic environments or systems by enhancing the AI agents with a knowledge base related to the environment the AI agent is tasked with analyzing. The AI agent can build the knowledge base automatically facilitating rapid adaptation to new environments, contexts, and states. Advantageously, the knowledge base provides accurate information related to the dynamic environment or system. With relevant information available to the AI agent, the AI agent may be less likely to generate falsifications, take inappropriate actions, or otherwise hallucinate.

In some embodiments, the AI agent generates one or more agent-based model simulations for a system indicated in an inbound task or prompt. For example, the agent-based model simulation may include several autonomous agents that each operate based on a set of rules that define their interaction with the environment, goals, and interactions with other agents of the system. Simulations can be run for various configurations, parameters, and/or initial conditions, allowing the AI agent to develop a deep understanding of a complex system within its knowledge base. The systems and methods described herein may prevent hallucinations while providing information to an AI agent for results synthesis in the form of testing hypotheses presented in the inbound task, predicting future outcomes, and taking decisive actions.

While increasing accuracy of the responses or actions generated by the AI agents and/or large language models, the systems and methods described herein may also improve agent-based models by tailoring the agent-based model simulation for a particular task (e.g., question, prompt, hypothesis test, etc.). In some embodiments, the AI agents automatically build the agent-based simulation based on the task and may eliminate the potential for human error and suboptimal model design. For example, the AI agent may choose from model agents (e.g., the agents used within the agent-based model) from a set of templates based on a semantic comparison of the inbound task and metadata for candidate agents, and build an agent-based model using the chosen agents. Fully constructed agent-based model simulations can also be selected from a library of previously constructed models, or agents themselves can be generated by adding rules or generated code for the agent based on the inbound task.

In some embodiments, the systems and methods described herein automatically allocate appropriate computational resources to execute the agent-based model simulation. Resources can be allocated according to the specific agents included within the agent-based model. For example, various model agents can be split between different types of hardware according to the computational needs of the agents. Model agents or their computations can be performed on an efficient hardware choice, for example, leveraging GPUs for parallel simulations and/or matrix manipulations, CPUs for general computations, and FPGAs for highly specific calculations. Leveraging appropriate hardware can decrease computational time, the number of computations performed, and power usage, leading to overall efficiency gains compared to traditional agent-based model simulations.

### Overview

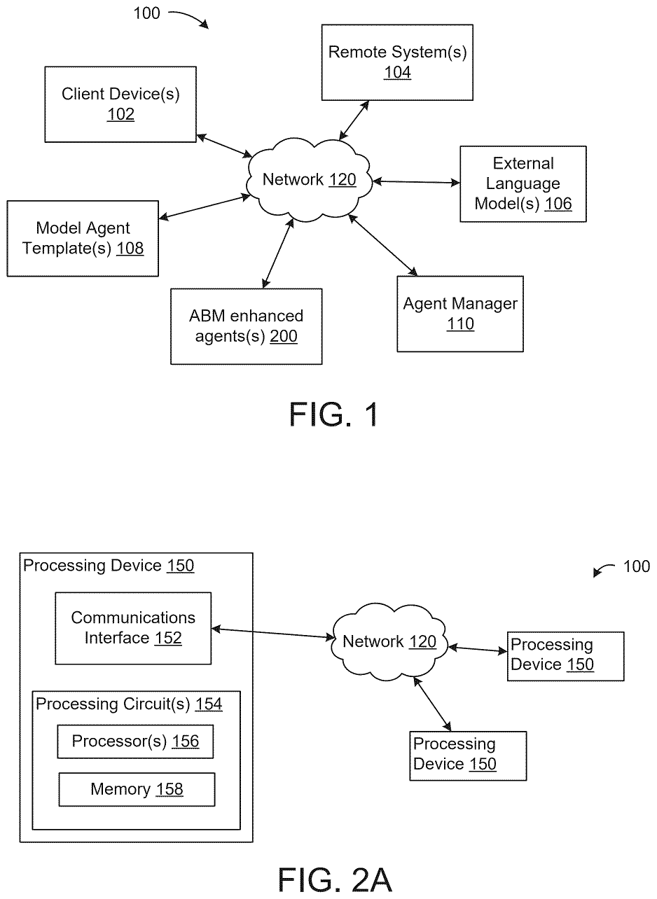

FIG. 1 shows a block diagram overview of an agent-based modeling (ABM) enhanced response system 100 according to some embodiments. The ABM enhanced response system 100 may be configured to respond to inbound tasks (e.g., prompts, jobs, stimuli, triggers, etc.). For example, the ABM enhanced response system 100 may be configured to generate textual output in response to a query related to a real-world system. In some embodiments, the ABM enhanced response system 100 is configured to update a display with the textual output. The ABM enhanced response system 100 may generate email, text messages, notifications, and/or instructions for a user interface (e.g., for a web browser, etc.) using the generated textual output.

The ABM enhanced response system 100 may generate one or more agent-based model simulations in order to respond to the task. The agent-based model may be configured to represent any real-world system using a number of model agents representing entities in the real-world system that are programmed (e.g., provided rules) to interact similarly to their real-world interactions. The agent-based model may be used to generate data relevant to the task, which can be used in responding to the task. In some embodiments, the ABM enhanced response system 100 generates an input to an application programming interface (API) based on the summary. The input may be configured to effect a change within the real-world system represented by the agent-based model to exhibit behavior observed in the agent-based model simulation.

The ABM enhanced response system 100 may be configured to serve any type of real-world system. As used herein, a real-world system may refer to any number of interacting entities (e.g., objects, devices, persons, animals, molecules, cells, packages, businesses, vehicles, etc.). Non-limiting examples of real-world systems include a supply chain, a manufacturing plant, a computer, a multicellular organism, an air conditioning unit, a virus, or any other system.

In FIG. 1, the ABM enhanced response system 100 is shown to include a number of components communicably coupled by a network 120. For example, the ABM enhanced response system 100 may include one or more client devices 102, one or more remote systems 104, one or more external language models 106, agent model templates storage 108, an agent manager 110, and one or more ABM enhanced agents 200. The network 120 can include routers, switches, antennas, computers, and any other hardware required to communicate information between the components of the ABM enhanced response system 100. A portion of the network 120 may be wireless and/or a portion of the network 120 may be wired. The network 120 may include one or more networks with routers to facilitate data transfer between the different networks. Communication using the network may include generating one or more signals for communicating information over the network 120. The sending device may generate an electronic signal conforming to an encoding scheme. For example, the sending device may generate data frames to communicate data using the Internet protocol over Ethernet.

The one or more client devices 102 may be configured to facilitate interaction between a user of the ABM enhanced response system 100 and one or more other components of the ABM enhanced response system 100. For example, the one or more client devices 102 may be configured to display a user interface. In some embodiments, the user of the ABM enhanced response system 100 enters prompts into the user interface on the one or more client devices 102. The user may, for example, type a prompt into an editable text field and interact with another interface element (e.g., a button, etc.) to transmit the prompt to the one or more ABM enhanced agents 200. The user interface may also allow scheduling of the one or more ABM enhanced agents 200 (e.g., for prompts or other tasks that are run periodically, etc.).

The one or more client devices 102 may also provide output from the ABM enhanced response system 100 to the user. Output may be displayed via the user interface and can provide notifications, alerts, suggestions, etc. related to the real-world system queried in the task input.

In some embodiments, the one or more client devices 102 are configured to receive instructions for the user interface. The instructions may be provided by another component of the ABM enhanced response system 100. For example, the agent manager 110 may communicate instructions over the network 120 in the form of JavaScript, Cascading Style Sheets, or any other suitable format for instructions. In some embodiments, the one or more client devices 102 execute the instructions to generate the user interface within a web browsing application. Alternatively, the one or more client devices 102 may have proprietary software installed (e.g., an application, etc.) to interpret the instructions.

Non-limiting examples of the one or more client devices 102 may include a laptop, a desktop, a phone, a tablet, wearable devices, or any other electronic device capable of transmitting and/or receiving information.

In addition to providing outputs from the ABM enhanced response system 100 to the user, the one or more client devices 102 may also provide additional context related to the inbound task. For example, the one or more client devices 102 may provide sensory information from a camera or microphone on the one or more client devices 102. In addition, text and/or graphics from an interface displayed on the one or more client devices 102 may be included with the task. The one or more client devices 102 may communicate the task along with any additional context via the network 120 to the one or more ABM enhanced agents 200 for processing. In some embodiments, the one or more client devices 102 (e.g., the application or user interface provided by the one or more client devices 102) summarizes the additional context into text to facilitate processing by the language models of the ABM enhanced response system 100.

The one or more remote systems 104 may represent other systems with which the one or more ABM enhanced agents 200 can interact. Non-limiting examples of the one or more remote systems 104 include email systems, calendar application servers, resource scheduling systems (e.g., logistics systems, computational equipment, shipping services, on-site customer service scheduling, meeting room reservation systems, etc.), rideshare services, food delivery services, shipment tracking services, internal business applications, and webservers.

The one or more remote systems 104 may provide both input for a task and receive output from the one or more ABM enhanced agents 200 in response to an inbound task. In some embodiments, when an inbound task is received, the one or more ABM enhanced agents 200 initiate a search for relevant information from the one or more remote systems 104. The search may be semantic, for example, similar to a retrieval augmented generation (RAG) architecture. The search results (e.g., documents or other content returned by the search) may be provided for additional context within a prompt to a language model (internal or external) by the one or more ABM enhanced agents 200. In addition, search results may be used to generate or select one or more model agents for the one or more ABM enhanced agents 200.

The one or more ABM enhanced agents 200 may also provide output in addition to updates to a view within a user interface. For example, the one or more ABM enhanced agents 200 may interact with one or more of the one or more remote systems 104 to effect change within the real world. In some embodiments, the one or more ABM enhanced agents 200 may generate an output that configured to cause a real-world system to exhibit behavior similar to that observed within an agent-based model simulation of the one or more ABM enhanced agents 200. For example, after several simulations of an agent-based model, the best (e.g., highest scoring) model (e.g., according to an objective function or other scoring methodology) may be selected for execution by the one or more ABM enhanced agents 200. The one or more ABM enhanced agents 200 may activate and/or provide data to the computer systems controlling the real-world system. For example, the one or more ABM enhanced agents 200 may generate an input for an API to initiate a resource transfer between two warehouses or between two departments to improve completion time of projects. In other input scenarios, the one or more ABM enhanced agents 200 may schedule laboratory time to study effects of drugs or to schedule time for events within a person's calendar.

The ABM enhanced response system 100 may include one or more external language models 106. The one or more external language models 106 may be used by the one or more ABM enhanced agents 200 to generate natural language outputs, to interpret input task semantically, to develop insight related to the inbound task or an agent-based model simulation related to the inbound task, etc. While the one or more ABM enhanced agents 200 are often referred to as using the one or more external language models 106 herein, in some embodiments, the one or more ABM enhanced agents 200 may include one or more internal language models (e.g., within the same device or cluster as the one or more ABM enhanced agents 200 or dedicated to a particular ABM agent). In some embodiments, the one or more ABM enhanced agents 200 may use both an internal language model and the one or more external language models 106. For example, the one or more ABM enhanced agents 200 may include a smaller language model or a language model fine-tuned to a particular task, whereas the one or more external language models 106 may include general language models and/or large language models. The one or more ABM enhanced agents 200 may select the language model used based on the task, such as, for example, to improve computational efficiency and decrease computational cost. Where a component of the ABM enhanced response system 100 is described as using one or more external language models 106, using an internal language model, or a combination of both internal and external language models should be considered in the scope of this disclosure.

The one or more external language models 106 may include one or more large language models (LLMs). one or more multi-modal language models (MMLMs), and/or one or more small language models (SLMs). The language models may be of varying architectures including transformer-based architectures such as generative pretrained transformers (GPTs), bidirectional encoder representations from transformers (BERT), recursive neural networks (RNNs), etc. MMLMs may be used to process image-based documents (e.g., file types such as portable document format, portable network graphics, etc.) or other image-based content received from the one or more remote systems 104 or other sources of information. SLMs may be trained to process specific types of documents or within a particular context. Advantageously, SLMs may provide increased accuracy within the context they were trained and use fewer parameters and/or computations to generate a result.

The one or more ABM enhanced agents 200 may be configured to respond (e.g., generate output, take an action, etc.) to a task (e.g., an external stimulus a prompt, a trigger from measurements or changes of the one or more remote systems 104 or the one or more client devices 102, a scheduled execution, etc.) In some embodiments, the one or more ABM enhanced agents 200 may receive the task by polling for changes to the one or more client devices 102 and/or the one or more remote systems 104. For example, the one or more ABM enhanced agents 200 may monitor a number of measurements and trigger execution when one or more measurements satisfy a trigger criterion. The one or more ABM enhanced agents 200 may also automatically receive triggers (e.g., events, execution requests, prompts, etc.) from the one or more client devices 102 or the one or more remote systems 104. The one or more ABM enhanced agents 200 may subscribe to such triggers and/or provide and API where the one or more client devices 102 and/or one or more remote systems 104 can input the trigger to the one or more ABM enhanced agents 200. Additionally, the one or more ABM enhanced agents 200 may trigger based on a schedule (e.g., periodic, selected dates or times, etc.).

The one or more ABM enhanced agents 200 may determine whether a response to a task would benefit from performing a simulation (e.g., an agent-based model simulation). For example, the task may relate to a real-world system (e.g., a physical system) for which the one or more ABM enhanced agents 200 has little or no experience. If the one or more ABM enhanced agents 200 determines that the response would benefit from performing a simulation, the one or more ABM enhanced agents 200 may be configured to generate an agent-based model simulation to provide additional information and/or insight related to the task. In some embodiments, the one or more ABM enhanced agents 200 may select or generates model agents to add into the agent-based model simulation. For example, the model agents may be added based on a semantic comparison between the task and/or metadata for a number of model agents or model agent templates (e.g., stored in the agent model template storage 108). If a suitable model agent cannot be selected from the agent model template storage 108, the one or more ABM enhanced agents 200 may generate a model agent, for example, by adding interaction rules generated from the task into a general or generic model agent. In some embodiments, the one or more ABM enhanced agents 200 selects from one or more stored simulation models (e.g., a complete configuration) that had been previously generated and/or executed.

The one or more ABM enhanced agents 200 may determine the necessary resources for executing the agent-based model simulation and allocate those resources, for example, from GPUs, CPUs, and/or FPGAs. In some embodiments, the one or more ABM enhanced agents 200 determines an allocation of the different types of computational resources (e.g., the GPUs, CPUs, and/or FPGAs) according to an objective function. The objective function may include a term related to the cost (e.g., computational or monetary) of executing the agent-based model simulation and the time required to execute the agent-based model configuration. By improving an appropriately weighted objective function, the one or more ABM enhanced agents 200 may perform a trade-off between computational cost and execution time.

The one or more ABM enhanced agents 200 may process the output of the agent-based model simulation and add information related to the simulation to a knowledge base related to the real-world system represented by the agent-based model simulation. In some embodiments, the one or more ABM enhanced agents 200 processes the outputs (e.g., outcomes, results, etc.) of the simulation prior to updating the knowledge base using the outputs. For example, the one or more ABM enhanced agents 200 may summarize (e.g., condense, compress, etc.) the outputs. In some embodiments, the one or more ABM enhanced agents 200 may generate insight related to the real-world system from the simulation and add the insight into the knowledge base. For example, the one or more ABM enhanced agents 200 may analyze trends (e.g., correlations, etc.) between simulation properties and/or the outputs of the simulation. The one or more ABM enhanced agents 200 may also determine the simulation properties that have the greatest effect on the outputs. Insights added to the knowledge base may be used to take an appropriate action or otherwise respond to the task.

In some embodiments, the one or more ABM enhanced agents 200 are configured to compare simulation results to the current knowledge base to determine if the outputs conflict with what has already been stored in the knowledge base. If the outputs conflict with the knowledge base the one or more ABM enhanced agents 200 may take an action to resolve the conflict. For example, the one or more ABM enhanced agents 200 may determine that the knowledge base should be updated because the conflicting information is outdated (e.g., the real-world system has since evolved). Alternatively, the one or more ABM enhanced agents 200 may rerun the agent-based model simulation with different parameters (e.g., improved temporal resolution, different assumptions, more model agents, etc.) in order to determine if the simulation results are accurate.

In some embodiments, the one or more ABM enhanced agents 200 generate multiple simulations, for example, for similar models with a different number of agents, different parameters, or different actions taken by the agents. The one or more ABM enhanced agents 200 may be configured to explore different scenarios and determine a best simulation (and with it, a best set of actions or parameters for the simulations or agents of the simulations). For example, the one or more ABM enhanced agents 200 may perform an optimization by adjusting the parameters or other properties of the simulation based on the output of one or more previous simulations.

The one or more ABM enhanced agents 200 may generate action signals to initiate an action. Action signals may be electronic (e.g., digital) signals communicated over the network 120. For example, an action signal may include a communication to an API for one or more applications that can affect the real-world system queried by the task. The action signals may be communicated over any network access layer such as ethernet or Wi-Fi. The action signals may also include routing information, for example, using internet protocol (IP) and/or transmission control protocol (TCP) to ensure the signal and its information is delivered to the correct device and/or system. In addition, the action signal may include content for any type of application. For example, the action signal may include instructions for a display within a web browsing application or may include get and/or post methods within the hypertext transfer protocol (HTTP) for an API. The one or more ABM enhanced agents 200 may effect a change within a real-world system by changing parameters, initiating an action, etc. within an application or device controlling or affecting the real-world system or entities thereof.

The agent model templates storage 108 may store a number of templates for model agents (e.g., candidate model agents, etc.) that can be used for agent-based model simulations. The templates may have varying degrees of adaptability (e.g., number of parameters, the ability to add or remove rules, etc.) The templates may also relate to diverse real-world systems as described previously. Templates may represent a model agent for an entity of a real-world system. Non-limiting examples of model agent classes (e.g., types, kinds, etc.) include objects, devices, persons, animals, molecules, cells, packages, businesses, and vehicles. The templates may be stored with metadata related to the template and/or the entity represented by the model agent of the template. The metadata may facilitate selection of model agents using information from an inbound task. Metadata may include a description of the entity, a description of the rules included in the template, a number of rules included in the template, internal states of the entity, parameter names for the template, a description of the parameters, etc.

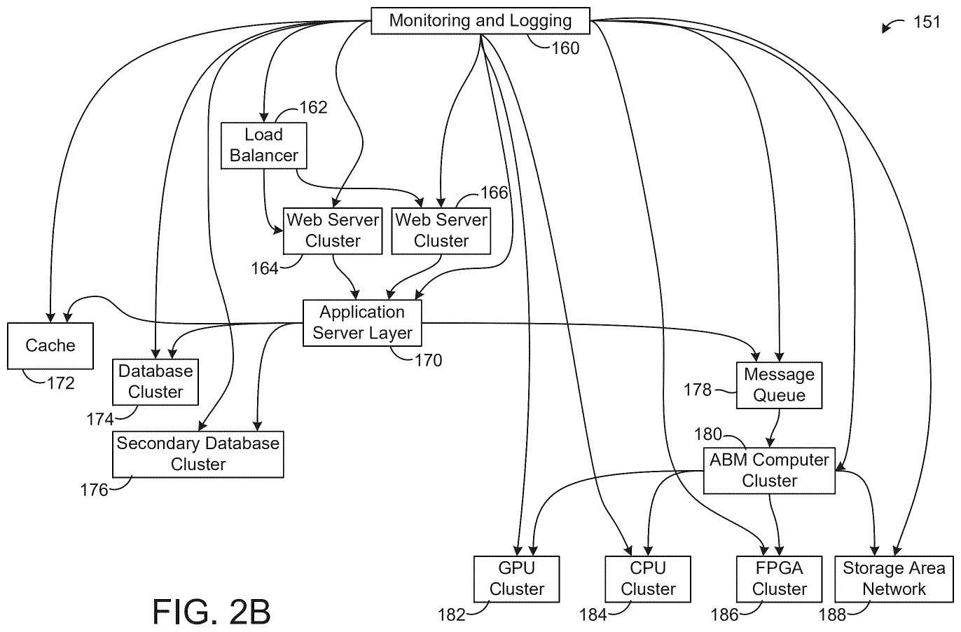

The agent manager 110 may be configured to coordinate the overall functionality of the ABM enhanced response system 100. For example, the agent manager 110 may manage schedules for the one or more ABM enhanced agents 200 or subscriptions for the one or more ABM enhanced agents 200. The agent manager 110 may also provide the APIs and/or web servers that allow user access (e.g., interaction, etc.) to the one or more ABM enhanced agents 200. For example, the agent manager 110 may generate instructions for the user interface displayed on the one or more client devices 102. The agent manager 110 may triage tasks and/or provide the tasks to the appropriate agent, for example, an agent configured to perform the task or already having information related to the task. The agent manager 110 may also maintain the resources for operating the one or more ABM enhanced agents 200 and/or executing the agent-based model simulations. For example, the agent manager 110 may reserve the resources allocated by the one or more ABM enhanced agents 200 for simulations. The agent manager 110 is described in more detail with reference to the architecture in FIG. 2B below.

### Hardware and Architecture

FIG. 2A shows a schematic block diagram of hardware suitable to implement elements of the ABM enhanced response system 100. Including the agent model templates storage 108, agent manager 110, and the one or more ABM enhanced agents 200 according to some embodiments. In some embodiments, the agent model templates storage 108, agent manager 110, and the one or more ABM enhanced agents 200 are distributed across several node computers within a cloud computing architecture. Alternatively, the agent model templates storage 108, agent manager 110, and the one or more ABM enhanced agents 200 may be implemented on one or more processing circuits of a computer (e.g., a server, workstation, desktop, etc.) or several local computers connected by a local intranet. The hardware (e.g., the cloud node, server, workstation, computer, etc.) of the ABM enhanced response system 100 is shown to be implemented by one or more processing devices 150. Each of the one or more processing devices 150 may implement one or more of the components (e.g., instruction sets, circuits, etc.) of the ABM enhanced response system 100 (e.g., the agent model templates storage 108, agent manager 110, and the one or more ABM enhanced agents 200, etc.). Additionally or alternatively, a component of the ABM enhanced response system 100 may be distributed across multiple of the one or more processing devices 150. For example, the agent manager 110 may require a large number of resources (e.g., distributed on multiple webservers), or multiple instances of the one or more ABM enhanced agents 200 may be distributed across multiple of the one or more processing devices 150.

In some embodiments, the hardware (e.g., the one or more processing devices 150) is available on demand for implementation of any of the components of the ABM enhanced response system 100. For example, a resource allocator or load balancer within a cloud architecture may instantiate (e.g., provision, etc.) additional instances of one or more processing devices 150 for implementing additional ABM enhanced agents 200 and/or executing multiple agent-based simulations simultaneously. The one or more processing devices 150 may be instantiated with resources based upon (e.g., commensurate with) the task they are perform. For example, a processing device for a large simulation may include more GPUs in the one or more processing devices 150. It is contemplated that one or more processing devices 150 may include a virtual machine. Multiple virtual machines may be operating on a physical set of hardware (e.g., a server blade, computer, rack, etc.)

In some embodiments, the one or more processing devices 150 are communicably connected over a network 120. The network 120 may include routers, switches, antennas, computers, and any other hardware required to communicate information between the components of the ABM enhanced response system 100. A portion of the network 120 may be wireless and/or a portion of the network 120 may be wired. The network 120 may include one or more networks with routers to facilitate data transfer between the different networks. Additionally or alternatively, the ABM enhanced response system 100 may be part of a single computer and may be communicably connected over a communications bus, wire, or by way of another conductive structure.

Each of the one or more processing devices 150 may include a communications interface 152. The communications interface 152 may be configured to send or receive data via the network 120. The data received by the communications interface 152 may be communicated to the component of the ABM enhanced response system 100 implemented by the respective processing device 150. Similarly, the component implemented may communicate information to the communications interface 152 to send data over the network 120. For example, the communications interface 152 may include a network interface card.

Each of the one or more processing devices 150 may include one or more processing circuits 154 having one or more processors 156 and memory 158. The one or more processors 156 may be configured to execute instructions stored on the memory 158. Some of the one or more processing devices 150 may also use the memory 158 for long term storage. For example, the one or more processing circuits 154 implementing a datastore (e.g., a knowledge base, the agent model templates storage 108, etc.) may include hard drive storage (e.g., magnetic, solid-state, etc.) to store the data.

The one or more processors 156 may be a general-purpose or specific-purpose processors, an application specific integrated circuit (ASIC), one or more field programmable gate arrays (FPGAs), a group of processing components, or other suitable processing components. The one or more processors 156 may be configured to execute computer code and/or instructions stored in the memory 158 or received from other computer readable media (e.g., CDROM, network storage, a remote server, etc.). The one or more processors 156 may be configured in various computer architectures, such as graphics processing units (GPUs), distributed computing architectures, cloud server architectures, client-server architectures, or various combinations thereof. One or more first processors can be implemented by a first device, such as an edge device, and one or more second processors can be implemented by a second device, such as a server or other device that is communicatively coupled with the first device and may have greater processor and/or memory resources.

The memory 158 may include one or more devices (e.g., memory units, memory devices, storage devices, etc.) for storing data and/or computer code for completing and/or facilitating the various processes described in the present disclosure. The memory 158 may include random access memory (RAM), read-only memory (ROM), hard drive storage, temporary storage, non-volatile memory, flash memory, optical memory, or any other suitable memory for storing software objects and/or computer instructions. The memory 158 may include database components, object code components, script components, or any other type of information structure for supporting the various activities and information structures described in the present disclosure. The memory 158 may be communicably connected to the processors and can include computer code for executing (e.g., by the processors) one or more processes described herein.

FIG. 2B is a block diagram of an architecture 151 illustrating various services suitable for implementing the ABM enhanced response system 100 according to some embodiments. FIG. 2B shows architectural layers or services each of which may be implemented by the one or more processing devices 150 or a processing devices 150 may implement multiple of the services. The architecture 151 is shown to include monitoring and logging servers 160, a load balancer 162, one or more webserver clusters (e.g., webserver cluster 164 and webserver cluster 166), an application server layer 170, a distributed cache 172, a database cluster 174, a secondary database cluster 176, a message queue 178, an ABM computer cluster 180, a GPU cluster 182, a CPU cluster 184, a FPGA cluster 186, and a storage area network 188.

The monitoring and logging servers 160 may be configured to continuously observe system metrics, resource usage, and application behavior to detect anomalies, security issues, or performance problems in real time. For example, the monitoring and logging servers 160 may alert system administrators via email or text message of any potential issues. The monitoring and logging servers 160 may also capture records of system events such as user access, configuration changes, and failed login attempts, which can be stored securely for auditing, for example, in the event of a security issue. The monitoring and logging servers 160 may span across multiple aspects of the ABM enhanced response system 100 including task ingestion (e.g., via a user interface or API) and responses generated by the one or more ABM enhanced agents 200.

The application server layer 170 may coordinate with the storage (e.g., distributed cache 172, the database cluster 174 and the secondary database cluster 176) as well as the services provided by the ABM computer cluster 180. For example, message queue 178 may include a number of tasks for the ABM computer cluster 180. For example, the ABM computer cluster 180 may host the one or more ABM enhanced agents 200 and the simulations thereof. Tasks may be provided through the application server layer 170 into the message queue 178 to be processed by the one or more ABM enhanced agents 200 in the ABM computer cluster 180. Similarly, the message queue 178 may provide results of the agent-based model simulations or actions from the one or more ABM enhanced agents 200 in the ABM computer cluster 180 back to the application server layer 170 where they can be provided to the user via the user interface. Simulation results, one or more ABM enhanced agents 200 outputs (e.g., insight, responses, actions, etc.) may also be communicated via the message queue 178 to the storage.

The ABM computer cluster 180 is shown to include clusters of various processor types. For example, the ABM computer cluster 180 may include a GPU cluster 182, a CPU cluster 184, and an FPGA cluster 186. Simulations from the one or more ABM enhanced agents 200 may be distributed across the GPU cluster 182, CPU cluster 184, and the FPGA cluster 186 based on the model agents and the number thereof. In addition, the ABM computer cluster 180 may include a storage area network 188 to provide shared data storage between the various nodes of the ABM computer cluster 180. For example, the storage area network 188 may facilitate intermediate results sharing within an agent-based model simulation and for the one or more ABM enhanced agents 200 to interpret results across multiple agent-based model simulations.

The application server layer 170 may be configured to provide results from the one or more ABM enhanced agents 200 and the agent-based model simulations thereof to the webserver clusters 164 or 166 to be provided (e.g., combined) with more static or less computationally intensive portions of the user interface. For example, the application server layer 170 may host APIs that are called via the user interface provided through the webserver clusters 164 or 166 to add tasks to the message queue 178. In some embodiments, the architecture 151 includes a load balancer 162 to balance the load between the webserver clusters 164 or 166. For example, the load balancer 162 may distribute sessions from multiple of the one or more client devices 102 between the webserver clusters 164 or 166. In addition, the load balancer 162 may direct sessions away from a failed webserver cluster to an operational webserver cluster.

In some embodiments, the agent manager 110 is implemented across several management layers of the architecture 151. The functionality of the agent manager 110 may be included in the load balancer 162, the webserver clusters 166, and the message queue 178. For example, the load balancer 162 may balance the load of the incoming requests to the web server and the message queue 178 may prioritize inbound requests and other stimuli for the cluster.

### Agent-based Model Enhanced AI Agent

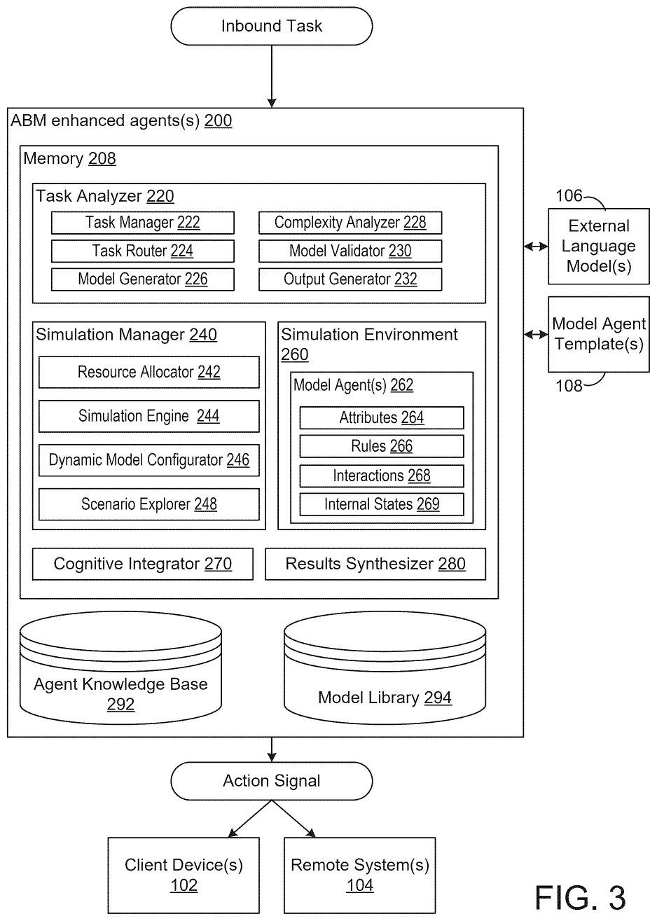

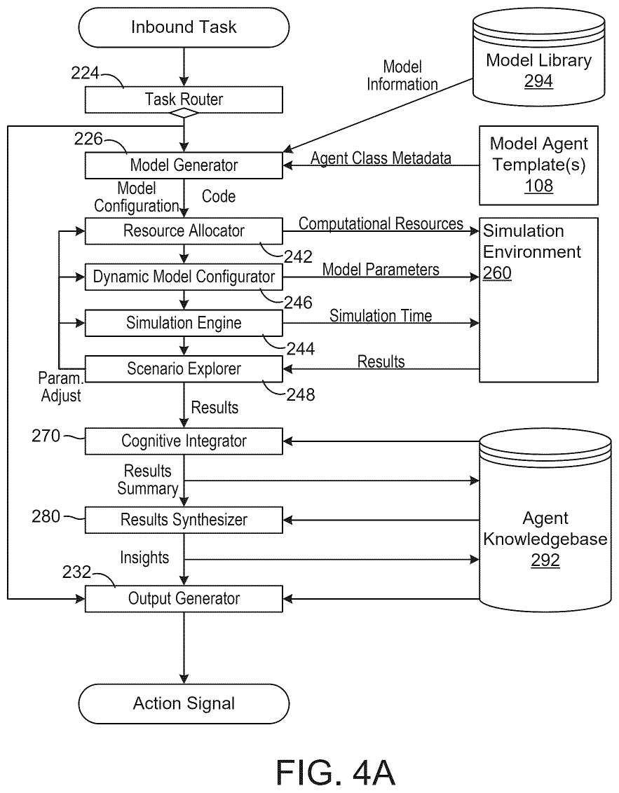

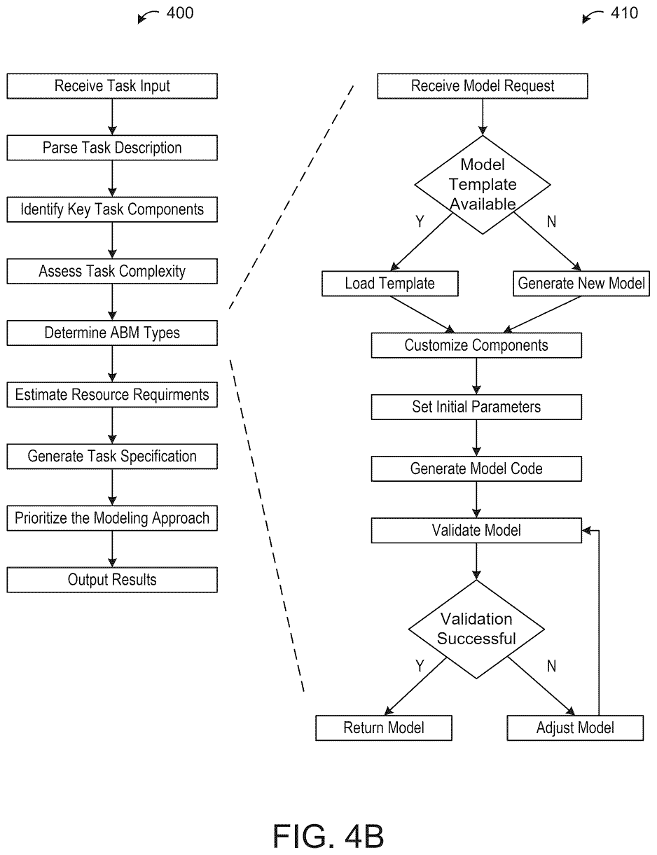

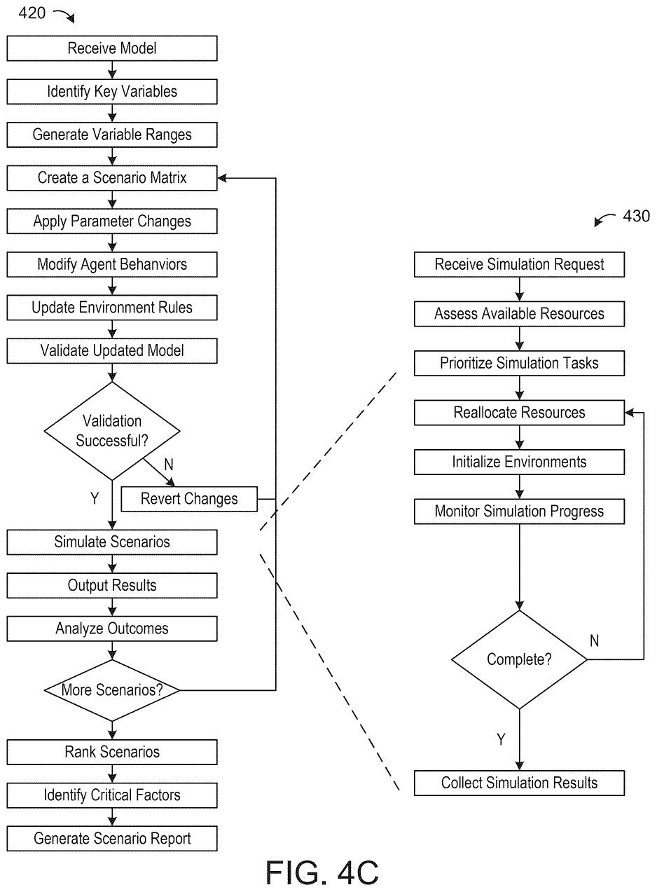

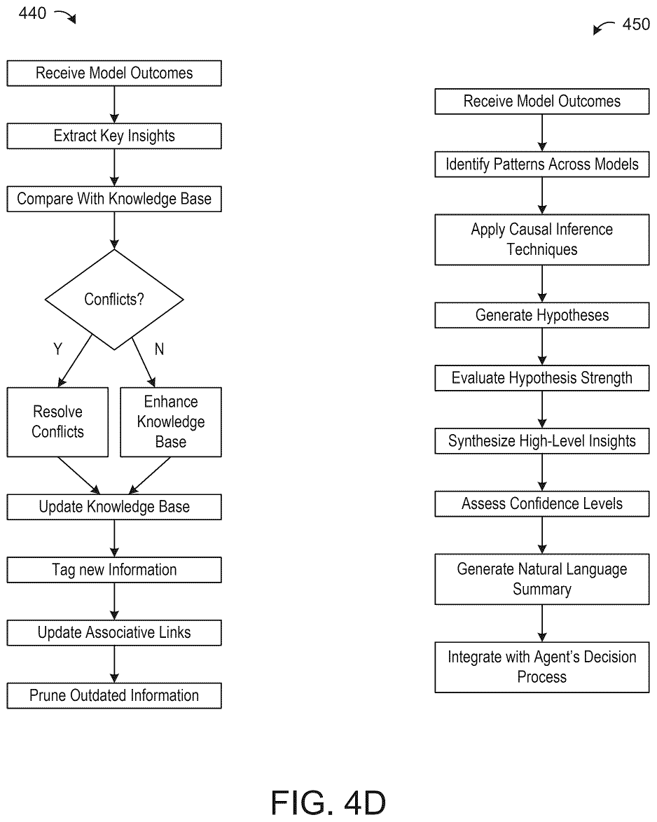

FIG. 3 is a schematic block diagram of an ABM enhanced agent 200 illustrating the internal components (e.g., instruction sets, processing circuits, etc.) according to some embodiments. FIG. 4A is a data flow diagram between the components of an ABM enhanced agent 200 illustrating the data and operational flow during processing of an inbound task, according to some embodiments. While not explicitly shown in FIG. 4A it should be understood that all downstream processing instruction sets (or circuits) may access any output generated by previous instruction sets (or circuits). For example, the inbound task may be available for each processing component. FIG. 3 provides a hardware centric view, whereas FIG. 4A provides a view centered around the data. FIGS. 3 and 4 are referred to below to describe the one or more ABM enhanced agents 200.

The one or more ABM enhanced agents 200 are shown to include a task analyzer 220, a simulation manager 240, a simulation environment 260, a cognitive integrator 270, and a results synthesizer 280. The task analyzer 220 may include a number of components (e.g., instruction sets and/or circuits) configured to manage execution of an inbound task. The task analyzer 220 is shown to include a task manager 222; a task router 224, for example, to determine whether an agent-based model simulation should be executed or whether the execution of an agent-based model simulation is warranted; a model generator 226, for example, to generate a configuration of an agent-based model simulation; a complexity analyzer 228, for example, to determine an amount of computational resources for the agent-based model simulation; a model validator 230, for example, to determine if the agent-based model simulation is configured properly; and an output generator 232, for example, to generate an output related to the inbound task. The task manager 222 may manage completion of a task (e.g., from receiving the inbound task to generation of an action signal that can be communicated to the one or more client devices 102 and/or the one or more remote systems 104. The task manager 222 may coordinate execution of the components of an ABM enhanced agent 200 in response to an inbound task as shown in FIG. 4A. For example, the task manager 222 may coordinate timing of the execution of the components ensuring that any dependent results have already been generated before the next component executes. The task manager 222 may also route data between the different components (e.g., instruction sets and/or circuits) ensuring that the inputs are available for processing. For example, the task manager 222 may perform the functionality of a main instruction set that executes during processing of the inbound task. The task manager 222 may pass data by reference (or by value) to each component of the data flow.

Each of the one or more ABM enhanced agents 200 may include a simulation environment 260 (or multiple simulation environments) configured to execute one or more agent-based model simulations. The simulation environment 260 may execute the agent-based model simulations on dedicated resources, for example, within the GPU cluster 182, CPU cluster 184, and FPGA cluster 186 as dictated by the configuration of the agent-based model simulation. The one or more simulation environments 260 may include a storage area network within the ABM computer cluster 180 to facilitate rapid and resource efficient communication between the various clusters 182-186 and the ABM enhanced agent 200.

Each simulation environment 260 may be configured to execute one or more agent-based model simulations. The agent-based model simulation may include one or more model agents representing an entity within a real-world system that is the subject of the simulation. For example, the model agents may have a number of parameters, rules, and interaction points that govern their behavior within the simulation. A model agent may interact with other model agents and with the simulated environment according to predefined rules (e.g., interactions, protocols) or dynamically evolving rules or strategies. Simulation of a large number of model agents can elucidate emergent behaviors that would otherwise be difficult to predict using traditional modeling techniques. The agent-based model simulation may incorporate stochastic elements to reflect variability found in real-world systems. Data generated by the agent-based model simulation may be analyzed to identify patterns, optimize parameters, and/or guide experimental design. In one example, the model agents represent cells of an organism and molecules of a drug in order to recommend drug candidates for further study in the real-world.

The simulation environment 260 may be managed (e.g., executed, run, configured, provisioned, etc.) by the simulation manager 240. The simulation manager 240 may include a number of components to instantiate (e.g., allocate resources for) and configure the simulation environment 260. The simulation manager 240 may include a resource allocator 242, for example, to provision or allocate a number of resources for the agent-based model simulation; a simulation engine 244, for example, to step forward in time through the agent-based model simulation or to execute the agent-based model simulation for a period of simulated time; a dynamic model configurator 246, for example, to provide parameters and/or additional rules to agent templates to configure the agent-based model simulation to a specific scenario; and a scenario explorer 248, for example, to analyze results and determine new parameters to simulate within the agent-based model simulation.

The one or more ABM enhanced agents 200 may include a knowledge base 292 for storing information it has learned through interactions (e.g., feedback related to previous tasks) and/or agent-based model simulations. For example, results of an agent-based model simulation may be stored in the knowledge base 292. The knowledge base 292 may be structured (e.g., a relational database, graph database, etc.), unstructured (e.g., natural language text), or a combination of both. In some embodiments, the configuration of the agent-based model simulation may dictate the configuration of at least a related portion of the knowledge base 292. For example, the knowledge base 292 may be configured to include certain results such as energy usage, cost, or other objective functions that may be relevant to all agent-based model simulations.

The one or more ABM enhanced agents 200 may also include a model library 294. The model library 294 may be configured to store previous agent-based model simulation configurations. Previously executed agent-based model simulations may be recalled and executed to provide additional data and/or insight for an inbound task that is similar to a previous inbound task. In some embodiments, a model from the model library 294 is recalled and reconfigured to generate knowledge or insight specific to the new inbound task.

The task analyzer 220 may include a task router 224 to determine whether an agent-based model simulation would be beneficial for responding to the inbound task. For some simple inbound tasks insight gained by executing an agent-based model simulation may not be necessary and may even unnecessarily use computational resources that increase energy usage and/or could be applied to other problems. For inbound tasks where the task router 224 determines executing an agent-based model simulation would not be beneficial or has a small benefit (e.g., such that it doesn't outweigh the cost associated with the simulation), the task router 224 may direct the task to an output generator 232 (e.g., bypassing the simulation of an agent-based model and directly generating the output). For inbound tasks where the task router 224 determines an agent-based model simulation should be executed, the task router 224 may direct the task towards the model generator 226.

In some embodiments, the task router 224 searches the knowledge base 292 of the one or more ABM enhanced agents 200 (e.g., of both the agent processing the inbound task and other agents) to determine if the task can be processed with the current knowledge base. If appropriate knowledge exists, the task router 224 may determine not to execute an agent-based model simulation and direct the task to the output generator 232. The task router 224 may determine a level of confidence for responding to the task based on the current state of the knowledge base 292. For example, if the task router 224 determines a confidence greater than a threshold level the task router 224 may decide not to execute an agent-based model simulation. In some embodiments, the task router 224 uses the output generator 232 or performs functionality similar to the output generator 232 to determine the level of confidence. The task router 224 may request that the one or more external language models 106 generate a response for the inbound task and indicate a level of confidence in that request. For example, the task router 224 may request that the one or more external language models 106 indicate its confidence explicitly (e.g., in numerical format such as on a scale of 0-10 or 0-100). Confidence may also be indicated less directly, for example, based on whether or not the one or more external language models 106 provides a reference from the knowledge base 292 for its response.

In some embodiments, the task router 224 can prompt the one or more external language models 106 with information from the knowledge base 292 and request that the prompted language model provides a yes/no response indicating whether it has enough information to generate a response for the task or whether the response would benefit from information garnered from the results of an agent-based model simulation. For example, the task router 224 may provide reasons why agent-based model simulations are beneficial (such as tasks that contemplate multiple scenarios or an optimization of a parameters, etc.), thereby providing the one or more external language models 106 with context that can be used to correlate to the semantics in the inbound task to make the determination of whether executing an agent-based model simulation would be beneficial to the response. The task router 224 may also employ one-shot or multi-shot prompting by providing one or more examples of tasks that benefited from results of an agent-based model simulation and/or one or more examples of tasks that did not or would not benefit from the results of an agent-based model simulation.

In some embodiments, the task router 224 is rules-based. For example, the task router 224 may route the task to the model generator 226 or the output generator 232 based on how the task was received by the ABM enhanced response system 100 or the one or more ABM enhanced agents 200. The routing may be performed based on the API endpoint that received the task request, a user interface element (e.g., button, select box, text entry box, etc.) used to communicate the task to the ABM enhanced response system 100, and/or particular keywords in the prompt.

The task router 224 may use a combination of both rules-based and language model-based decision making strategies. For example, and as described above, the task router 224 may use a language model to determine a level of confidence related to the ability of the ABM enhanced agent 200 to respond to the task and then compare that level of confidence to the probability in a rules-based approach.

### Model Generation and Resource Provisioning

In some embodiments, the one or more ABM enhanced agents 200 include a model generator 226 to determine a model configuration for a task. As shown in FIG. 4A, the model generator 226 may receive the task from the task router 224 and generate a model configuration and/or code (e.g., instructions, etc.). A model configuration may include a listing of model agents (e.g., entities and/or interaction rules) to be included in an agent-based model simulation. The model configuration may be provided in a binary format (e.g., in an object or other coding structure in memory) or in a text-based form (e.g., an object notation such as JavaScript Object Notation (JSON) or extensible markup language (XML) in memory or as a file transfer). Code generated by the model generator 226 may be represented in a high-level coding language (e.g., C++, Python, etc.) that may be compiled within the simulation environment 260, an intermediate language (e.g., low-level virtual machine (LLVM), three-address code (TAC), etc.), GPU programming languages such as compute unified device architecture (CUDA) C or parallel thread execution (PTX), or a combination of multiple languages that can be split across the ABM computer cluster 180 including the GPU cluster 182, the CPU cluster 184, and/or the FPGA cluster 186.

In some embodiments, the code is generated from a code template. For example, the templates may include a number of predefined model agents or model agent containers within which interaction rules may be added. The templates may be in a high-level language and then compiled after the configuration has been added to the template. Alternatively, the templates may be in an intermediate representation. For example, the one or more external language models 106 may be used to combine the configuration with the code templates to generate an intermediate representation of the code to output from the model generator 226.

In some embodiments, the model generator 226 is configured to select one or more model agents for an agent-based model simulation. The selection may be from a number of predefined model agents based on a semantic comparison between metadata for a plurality of the predefined (e.g., candidate) agents and an input task. For example, each of the one or more agents selected represents an entity of the real-world system indicated in the inbound task. Model agents may be selected individually or selected as a set, for example, in a partially or fully configured agent-based model simulation. Previously stored agent-based models may be stored in the model library 294 for recall and reuse in processing of another task.

Model agent selection may be performed based on a semantic analysis between the inbound task and the predefined model agents and/or the configured agent-based models. The model generator 226 may perform a semantic analysis between text for the predefined model agents (or the configured agent-based models) and text for the inbound task. The inbound task may include text or a text-based section that can be used for the semantic analysis, whereas the model generator 226 may generate the text for the predefined model agents (or the configured agent-based models) based on metadata for the predefined model agents (or the configured agent-based models). The text for a predefined model agent (or a configured agent-based model) may include or be based upon multiple types of metadata. For example, the metadata used to generate the text may include the name of the predefined model agent (or the configured agent-based model); a description of the predefined model agent (or the configured agent-based model); rules within the predefined model agent (or the configured agent-based model) including the code, description, or comment for the rules; example reasons why the predefined model agents (or the configured agent-based models) would be included in an agent-based model simulation or any other appropriate text associated with the predefined model agent (or the configured agent-based model).

Semantic analysis may be performed using multiple methodologies. In a first methodology, semantic analysis is performed by comparing vector embeddings of the text for the predefined model agents (or the configured agent-based models) with a vector embedding of the text for the inbound task. Vector embeddings may be generated using any word or text embedding model. For example, the vector embeddings may be based on a bag-of-words model or a model that takes into account more context based on the order of the words (e.g., a sentence-wise embedding model, etc.). The vector embeddings may be compared based on a distance metric (e.g., a cosine distance, Euclidean distance, etc.). For example, the semantic analysis may include calculating the distance metric between each of the vector embeddings of the text for the predefined model agents (or the configured agent-based models) with the vector embedding for the text of the inbound task. The predefined model agents (or the configured agent-based models) with the smallest distance or a distance that satisfies a threshold criterion may be selected.

In a second methodology, semantic analysis is performed by way of a language model (e.g., the one or more external language models 106). For example, the text for the predefined model agents (or the configured agent-based models) and the text for the inbound task may be included in a prompt for the language model. For example, the prompt may include a request to determine which of the predefined model agents (or the configured agent-based models) provided with the prompt should be included in an agent-based model simulation or which of the predefined model agents (or the configured agent-based models) provide would provide the most relevant information for the task if included in a simulation. The text for all predefined model agents (or the configured agent-based models) may be provided and analyzed by a single prompt to the language model or prompts may be provided sequentially, for example, providing text for a single predefined model agent (or the configured agent-based model) and the inbound task and requesting the language model to determine if the predefined model agent (or the configured agent-based model) should be included in the agent-based model simulation.

The model generator 226 may select the predefined model agents (or the configured agent-based models) using any methodology for the semantic analysis. In addition, the model generator 226 may use a chain-of-thoughts or other sequential reasoning or code to determine the model configuration. For example, the model generator 226 may first perform the semantic analysis to determine which of the predefined model agents (or the configured agent-based models) should be included in the agent-based model simulation. After the predefined model agents (or the configured agent-based models) have been selected, the model generator 226 may determine an appropriate number of each type of the selected model agents (or the selected configured agent-based models).

In some embodiments, the model generator 226 is configured to favor configured agent-based models over selecting multiple model agents. The model generator 226 may first attempt to select configured agent-based models using a semantic analysis. If the selection fails (e.g., all distances between text embeddings are above a threshold or the language model indicates that none of the configurations would provide data to respond to the task), the model generator 226 may then try to select individual predefined model agents. In some embodiments, if individual model agents cannot be selected, the model generator 226 generates new model agents.

The model generator 226 may be configured to generate new model agents by adding agents to model templates. The model generator 226 may select parts (e.g., rules, attributes, interactions, etc.) for a new model agent based on a semantic analysis. Alternatively, the model generator 226 may use the one or more external language models 106 to generate code for the parts (e.g., rules, attributes, interactions, etc.) that can be added to a model agent. A combination of selecting the predefined model agents and generating them can be performed. For example, each of the predefined model agents may be on a continuum of how complete they are from fully defined (e.g., all rules, attributes, and interactions defined) to empty. The model generator 226 may select the closest predefined model agent and then add any of the types of parts of the model agent to customize the predefined model agent for the particular task. Similarly, the model generator 226 may also determine parameters for any of the parts of the predefined model agents. For example, the model generator 226 may determine parameters using text describing the parameter and text for the inbound prompt.

In some embodiments, the model generator 226 is also configured to determine parameters that are a subject of the inbound task. For example, the inbound task may include determining the best parameters for a certain scenario or environment (e.g., an optimization). The model generator 226 may flag or otherwise indicate the parameters that are free variables to be explored (e.g., modified, adjusted, changed, etc.) during simulation. The model generator 226 may determine an initial condition for the free variables, for example, an estimate at which any optimization or exploration is to begin.

In some embodiments, the model generator 226 is configured to analyze task complexity. The estimate of task complexity can provide insight related to the number of model agents that are to be included in the agent-based model simulation or the number of each type of model agents that are to be included in the agent-based model simulation. In some embodiments, the model generator 226 uses the one or more external language models 106 to determine the task complexity and/or a number of model agents to include in the agent-based model simulation. The model generator 226 may adjust the output model configuration and/or code based on the number of model agents, thereby configuring the agent-based model simulation according to the task complexity.

The model generator 226 may be configured to validate the agent-based model configuration or the code before it is output and used by the components of the simulation manager 240. For example, the model generator 226 may use the model validator 230 to perform another semantic comparison between text for the generated model configuration and the text of the inbound task. Text for the model configuration may be the configuration itself (e.g., in JSON, etc.) or text based on the components added to the model. The model validator 230 may determine that the model is valid if the distance between the text embeddings is below a threshold. In some embodiments, the model generator 226 generates more than one model configuration. The additional configurations may be generated using different language models, different prompts, different versions of the semantic analysis (e.g., embedding-based or language model-based), etc. The model validator 230 may generate a similarity measure between the models and determine that the model is valid if the similarity is greater than a threshold. Alternatively, the model generator 226 may generate multiple models, and allow all to be executed. The model validator 230 may be configured to determine whether the model is valid based on a comparison of the outputs of the simulation and/or the insight generated therefrom by the cognitive integrator 270 or the results synthesizer 280.

In some embodiments, the resource allocator 242 receives the model configuration and/or the code from the model generator 226 and provisions the computational resources for the simulation environment 260 using the code. For example, the resource allocator 242 may provide a virtual machine configuration or similar hardware specification for the simulation environment 260. The resource allocator 242 may determine the number of GPUs, CPUs, and/or FPGAs to perform the simulation and request those resources from the ABM computer cluster 180. In some embodiments, the resource allocator 242 also provides an amount of time the simulation will run and reserves the resources in the ABM computer cluster 180 for that amount of time.

The resource allocator 242 may use the complexity analyzer 228 in order to determine the resource requirements. The complexity analyzer 228 may be configured to calculate the amount of time an execution of the agent-based model simulation would take for a given resource allocation. In some embodiments, the complexity analyzer 228 also determines the memory requirements for the given resource allocation of CPUs, GPUs, and FPGAs. For example, the complexity analyzer 228 may generate a multidimensional function describing the outputs of time and/or memory usage based on a vector input indicating the number or amount of CPUs, GPUs, and FPGAs allocated to the simulation. In some embodiments, the resource allocator 242 determines an appropriate allocation based on the results (e.g., the time or memory output, or the multidimensional function) calculated by the complexity analyzer 228.

In some embodiments, the complexity analyzer 228 uses a rules-based approach to determine the resource requirements for the execution. For example, each model agent may be associated with a number of CPUs, GPUs, and FPGAs required to execute the model agent, the memory requirements, and the amount of time executing the model agent requires. The complexity analyzer 228 can totalize the number of CPUs, GPUs, and FPGAs required to execute the model agent and the memory requirements based on the total number of each type of model agent. Total processing time may be calculated based on the time for each of the model agents and the number of steps (e.g., iterations, time periods, etc.) in the model simulation. For example, by summing the time for each model agent and multiplying by the number of steps.

In some embodiments, the complexity analyzer 228 causes the code to be executed using various hardware configurations. Code execution provides an accurate estimate of the time and/or memory requirements, but takes more time and computations than the rule-based approach. In some embodiments, the complexity analyzer 228 uses a combination of a rules-based approach and an execution-based approach. For example, by executing a model agent of each type for various hardware configurations and then performing rules-based totalization to determine the total processing time and/or memory requirements for each hardware configuration. After the total processing time and/or memory requirements have been determined (e.g. through simulation or a combination of simulation and rules-based totalization) for a number of different hardware configurations, interpolation may be performed in order to generate the multidimensional function of the total processing time and/or memory as a function of the number or amount of CPUs, GPUS, and FGPAs allocated to the simulation.

In some embodiments, a number of scenarios (e.g., a scenario matrix or different parameters, agent quantities, or other variables to be explored during simulation) are to be run. The complexity analyzer 228 may determine the resources, time, and memory requirements for each or all of the scenarios. The resource allocator 242 can then provision the proper hardware from the ABM computer cluster 180 for either sequential or parallel simulations or a combination of sequential and parallel simulations.

The resource allocator 242 may determine the amount of resources to provision based on the multidimensional function generated by the complexity analyzer 228. In some embodiments, the resource allocator 242 selects a resource allocation that satisfies a time constraint. For example, the resource allocator 242 may select a resource allocation for which the total processing time is equal to a constraint value or less than a constraint value. In some embodiments, the resource allocator 242 uses an objective function to determine the best (e.g., optimal, improved, etc.) resource allocation. For example, the resource allocator 242 may perform an optimization using an objective function and a number of constraints. The objective function may include a term related to the number of each type of processing unit used (e.g., representing their cost or cost to operate, etc.), the memory resources, and/or the total processing time. The constraints may include similar terms, for example, ensuring that the total processing time, memory usage, or allocations of the types of processing units (e.g., CPUs, GPUs, FPGAs, etc.) are less than a respective constraint value.

FIG. 4B illustrates a flow of operations 400 for allocating resources for an agent-based model simulation based on an inbound task according to some embodiments. The flow of operations 400 may be performed by a combination of the model generator 226, the complexity analyzer 228, and the resource allocator 242.

The flow of operations is shown to start after the task router 224 has determined that an agent-based model simulation is to be performed by the ABM enhanced agent 200. The task input is received by the model generator 226. The model generator 226 may parse the task description into a number of portions and identify key task components for example, related to the model agents that are to be included in the agent-based model simulation. For example, the model generator 226 may identify portions of the inbound task to include in the semantic analysis to determine the model agents. In some embodiments, the model generator 226 also determines a task complexity that can be used to identify the number or different types of model agents.

FIG. 4B also illustrates flow of operations 410 for determining the agent-based model (and types thereof) according to some embodiments. For example, the key task components and the complexity may be part of a model request. The model generator 226 may evaluate the model request to determine if any templates (e.g., previously generated models, etc.) are available. If a model template for the model request (e.g., related to the inbound task) is available, that template may be loaded, otherwise a new model is generated. The model generator 226 may then customize the model, for example, by adding model agents, adding rules to agents, etc. based on a semantic analysis and then set the initial set of parameters. After the parameters have been set, the model generator 226 may be configured to generate the model code used to execute the agent-based model simulation, for example, using the one or more external language models 106 or a compiler to generate the code based on the model configuration. The model validator 230 may validate whether the model was created successfully. Validation may be performed as described above, for example, by comparing outputs, comparing models or results thereof generated using different techniques, or by ensuring the code executes. If the model is valid, it may be output of the model generator 226 or if the model is determined to be invalid it may be adjusted before validation is performed again.

Referring again to the flow 400, the complexity analyzer 228 may estimate the resource requirements for executing the generated model. The complexity analyzer 228 may generate a task specification, for example, including the computational time and memory usage based on different hardware configurations (e.g., different numbers of GPUs, CPUs, and/or FPGAs). In some embodiments, the resource allocator 242 can choose or prioritize a modeling approach based on the task specification generated by the complexity analyzer 228. The prioritized modeling approach may be output of the flow 400 and used in order to allocate (e.g., provision) an appropriate amount of hardware resources to execute the agent-based model simulation.

### Simulation Execution

In FIG. 3 the simulation manager 240 is shown to include a resource allocator 242, a simulation engine 244, a dynamic model configurator 246, and a scenario explorer 248 to manage the simulation environment 260 and execute agent-based model simulations. As described above the resource allocator 242 may provision the hardware resources to execute an agent-based model simulation based on the analysis of the complexity analyzer 228. The resource allocator 242 may also modify the resource allocation, for example, if the ABM enhanced agent 200 decides to perform more or less simulations, if additional hardware resources become available (e.g., as other simulations complete), or if the original estimates of the complexity analyzer 228 prove to be inaccurate. As shown in FIG. 4A, after hardware is allocated by the resource allocator 242, the simulation engine 244 may add values to the simulation environment 260. After preparation of the simulation environment 260, the simulation engine 244 may propagate the states of the agents within the simulation environment 260. Results are provided to the scenario explorer 248 where the results are analyzed to determine whether additional scenarios should be performed.

The simulation manager 240 may perform the simulations in multiple modes. In a continuously adjusted simulation mode, the simulation manager 240 may adjust the parameters of model currently being executed and analyze the results during the simulations progression. In a sequential mode, the simulation manager 240 may execute a simulation for a given period of time, adjust the parameters of the model based on an analysis of the results, reset the simulation back to its initial conditions, and perform another simulation. A batch mode is similar to the sequential mode; however, a number of simulations may be performed (e.g., in parallel or sequentially) prior to adjusting the parameters. In a synchronous mode, the simulation is synchronized to the real-world. For example, the initial conditions of the simulation may be based on the current conditions of the real-world system represented by the agent-based model simulation. The simulation manager 240 may perform multiple simulations starting at the current initial conditions to determine a best course of action.

The dynamic model configurator 246 may be configured to apply the parameter changes to the model. For example, the dynamic model configurator 246 may directly modify the model configuration and/or the model code. In some embodiments, the parameters are stored in memory locations within the simulation environment 260. The dynamic model configurator 246 may directly modify issue a command into the simulation environment 260 (e.g., via the message queue 178) in order to update the simulation parameters. In some embodiments, the dynamic model configurator 246 adjusts the model configuration and/or model code. For example, the parameters can be replaced in the configuration or code using an appropriate find and replace strategy (e.g., a regular expression, etc.) before re-executing the simulation. The dynamic model configurator 246 may also be configured to add agents to the agent-based model simulation. For example, the dynamic model configurator 246 may add additional copies of a model agent or add/subtract rules from a model agent. The model may be revalidated each time the parameters or model agents are updated. For example, the dynamic model configurator 246 may call the model validator 230 after updates have been completed.

FIG. 3. shows a block diagram of model agents 262 according to some embodiments. The model agents 262 may represent entities within the real-world system simulated in by the agent-based model simulation in the simulation environment 260. The model agents 262 are shown to include attributes 264, rules 266, interactions 268, and internal states 269. As described above, the attributes 264 include a number of parameters that may affect how the rules 266 and the interactions 268 operate. The model agents 262 may adjust the parameters to affect the configuration of the rules 266 and the 268. In some embodiments, the dynamic model configurator 246 also adjusts the initial value of the internal states 269, before starting another run of the simulation. The attributes 264, rules 266, and interactions 268 may all include (e.g., be based on) a number of variables (e.g., properties, etc.), that can be appropriately substituted into the attributes 264, rules 266, and interactions 268 prior to execution of the simulation.

In some embodiments, the dynamic model configurator 246 is configured to update the agent-based model simulation based on current information (e.g., measurements, observations, data, etc.) from a real-world system the agent-based model simulation is representing. For example, initial conditions and/or initial values of the internal states 269 may be updated based on the current information. In addition, the dynamic model configurator 246 may store a log of each update (e.g., adjustment, etc.) provided to the agent-based model simulation for later analysis. Logs allow down-stream functionality such as the cognitive integrator 270 or the results synthesizer 280 to correlate changes in parameters with changes in the results. The dynamic model configurator 246 may update the parameters based on a mapping generated by the model generator 226 (e.g., during model construction and/or based on semantic analysis of the inbound task and model agents). For example, the model generator 226 may generate a mapping between sensors and/or other sources of information in the real-world system and parameters in the agent-based model simulation. To facilitate generation of the mapping the inbound task may include a listing and description of the model agents.

In some embodiments, the dynamic model configurator 246 receives a number of independent parameter changes. Based on the hardware resources available and/or the number of simulation environments available, the dynamic model configurator 246 may provide the changes to multiple models in a batch mode, provide the changes sequentially, or may operate in a combination of a batch and sequential mode.

After parameters have been added to the agent-based model simulation and/or the model, the simulation engine 244 can cause the simulation to propagate forward in time. The simulation engine 244 may cause the simulation to step forward a certain number of iterations (e.g., model agent state updates, etc.), an amount of time, a number of simulated interactions, etc. Each model agent may be configured to maintain an internal state 169 (e.g., a vector or other multi-valued structure), which can be updated at each simulation timestep. A state update may include gathering relevant input, for example, from interactions with neighboring agents, environmental conditions, or global variables. Based on the input, each model agent may execute the rules 266 (e.g., algorithms, equations, etc.) to determine the change in its state or its next state. After states have been updated, the model agents 262 may calculate outputs or signals that affect other agents or the environment in subsequent timesteps, thereby facilitating the simulation of dynamic and emergent behaviors. The physical properties, conditions, etc. represented by the internal states 269 of the model agents 262 vary based on the entity of the real-world system that the model agents 262 may represent. Non-limiting examples of internal states 269 that are updated during a step of the simulation engine 244 include positions, velocities, temperatures, energy levels, health conditions, status, etc.

The scenario explorer 248 may be configured to determine simulation properties (e.g., parameters, rules, etc.) to use for each of a number of simulations that the one or more ABM enhanced agents 200 may execute in order to generate knowledge (e.g., data and/or text in the knowledge base 292 that can be used to respond to the inbound task. For example, the scenario explorer 248 may determine a matrix of scenarios (e.g., a structured multiplicity of scenarios) to explore certain aspects of the inbound task. The scenario explorer 248 may generate the scenarios based on the inbound task (e.g., text or other content of the task). The scenario explorer 248 may also determine the simulation properties for a next simulation based on the results of a previous simulation. For example, the scenario explorer 248 may perform an optimization or similar algorithm to continually update the simulation properties until the results reach a desired goal and/or stopping condition.

In some embodiments, the scenario explorer 248 determines a matrix of scenarios based on the content of the inbound task. The scenario explorer 248 may perform a semantic analysis in order to determine a matrix of scenarios (e.g., with different properties) to execute. The semantic analysis may be a comparison between (i) text for a number of properties (e.g., name, metadata, etc.) and text describing a number of analyses and (ii) text or other content of the inbound task. As described previously, the semantic analysis may be performed by way of a language model (e.g., the one or more external language models 106) or by comparing semantic embeddings of the content. For example, to determine the scenarios that should be run, the scenario explorer 248 may generate a prompt with the text for the number of properties, the text describing the analyses, the inbound task and a request to determine how to vary the properties in order to prove or disprove a hypothesis related to the inbound task.

In some embodiments, the scenario explorer 248 is configured to perform an optimization of an objective by modifying the properties of the agent-based model simulation. The scenario explorer 248 may parse the inbound task for content (e.g., text, information, etc.) related to an objective function indicated in the inbound task. The scenario explorer 248 may generate an objective function based on the content. For example, the inbound task may indicate that the objective is to minimize energy use or cost or a weighted sum of both cost and energy use. The scenario explorer 248 may generate one or more next properties for the simulation by adjusting previously used properties. In some embodiments, the scenario explorer 248 minimizes or otherwise improves the objective function using a gradient descent algorithm (e.g., sequential quadratic programming, etc.) the scenario explorer 248 may use the results from one or more previous simulations to determine a gradient of the objective function (e.g., near a current operating point) and move in the direction of the gradient or partially in the direction of the gradient (e.g., a direction having a positive dot product with the gradient).

In some embodiments, the scenario explorer 248 minimizes or otherwise improves the objective function based using a global optimization method. For example, the scenario explorer 248 may perform a genetic algorithm (e.g., representing the properties of the agent-based model simulation as “genes” for a simulation) or another biologically inspired optimization algorithm such as, ant colony optimization, or bird swarm optimization. In some embodiments, the scenario explorer 248 performs a Monte Carlo tree search algorithm in order to optimize or otherwise improve the objective function. For example, it may perform a number of selection (e.g., determining a path along the tree to explore), expansion (e.g., generating new nodes at the end of the selected path), simulation (e.g., executing the simulation for the new node), and backpropagation (e.g., using the results of the simulation to update the average value along the parent nodes) steps.

The scenario explorer 248 may generate scenarios (e.g., simulation parameters) for an active simulation such as that remains continuously running. The dynamic model configurator 246 may inject the new parameters as the simulation is running. Simulations may also be reset before running new simulations with properties determined by the scenario explorer 248. The method by which the properties are added to the simulation (e.g., after reset or in a continuously running simulation) may depend on the type (e.g., purpose, field, etc.) of the agent-based model simulation and the inbound task.

In some embodiments, the scenario explorer 248 may use a language model (e.g., one or more external language models 106) to analyze the results of the simulated scenarios. The scenario explorer 248 may perform a chain-of-thought (e.g., through one or more prompts) to analyze the results. For example, the scenario explorer 248 may provide the results of the simulated scenarios to the language model and request the language model to rank the scenarios (e.g., according to an objective). The scenario explorer 248 may request the language model identify crucial factors to the objective of the simulation results (e.g., which factors have the greatest positive or negative effect on the objective). For example, the identification of crucial factors may be after the language model has already ranked the scenarios, thereby allowing the language model to identify the factors that are common amongst high ranking or low ranking scenarios in a chain-of-thoughts approach.

The one or more external language models 106 may be used by the scenario explorer 248 to generate a scenario report. For example, the scenario explorer 248 may request a tabulated or text-based summary of the results. In some embodiments, the scenario explorer 248 may also request the one or more external language models 106 to determine whether the scenario explorer 248 should continue generating scenarios (e.g., whether the objective can still be improved). Alternatively, the scenario explorer 248 may evaluate a stopping criterion.

In some embodiments, the scenario explorer 248 may request that the language model generate scripts (e.g., code in high level language, an intermediate representation, and/or database queries) in order to perform any of the analysis performed by the scenario explorer 248. The scenario explorer 248 can thereby perform the analysis multiple times on multiple results without engaging the language models after each simulation. Advantageously, generating a script rather than executing the language model after each simulated scenario or batch of simulated scenarios reduces computational overhead and latency in generating the results.

FIG. 4C illustrates a flow of operations 420 for executing one or more agent-based model simulations in response to an inbound task according to some embodiments. The flow of operations 420 may be performed by a combination of the resource allocator 242, the simulation engine 244, the dynamic model configurator 246, and the scenario explorer 248. For example, the flow 420 may be performed by the one or more ABM enhanced agents 200.

The flow of operations 420 is shown to start after the model and simulation environment has been created (e.g., configuration or code has been generated by the model generator 226 and hardware provisioned by the resource allocator 242). Key variables may be identified by the scenario explorer 248 from the inbound prompt. For example, a semantic analysis may be performed on text for variables (e.g., properties, etc.) that are parameters in the generated agent-based model simulation and the text for the inbound prompt to determine which of the variables should be adjusted in the simulation. The scenario explorer 248 may also identify a range of valid values for the variables. For example, constraints may similarly be identified within the inbound task that are associated with the identified variables. The scenario explorer 248 may generate a scenario matrix for the variables within the identified valid ranges (or regions in a multidimensional variable space).

In the flow of operations 420, after the scenario matrix has been generated (e.g., by the scenario explorer 248), the variables may be applied as parameter changes to the agent-based model simulation. In addition, the variables may also be used to modify agent behaviors and/or update the environment rules. In some embodiments, after each time the model is updated (e.g., new parameters applied, agents added or removed, agent behavior changed, or environmental rules modified) the model is validated, for example, by the model validator 230. If the validation is unsuccessful, the changes may be reverted and either reapplied (e.g., with a different code generation strategy, prompt to generate the code, etc.) or different or new variables may be tried. If validation is successful, the agent-based model simulation may be executed, for example, by the simulation engine 244.

FIG. 4C also shows a flow of operations 430 for executing a simulation according to some embodiments. The flow 430 may also be performed by a combination of the resource allocator 242 and the simulation engine 244. After a simulation request is received the resource allocator 242 may assess the available computational resources. In some embodiments, the resource allocator 242 may determine that more resources are required to timely complete the simulations (e.g., because the scenario matrix is large etc.) and provision additional computational resources to run parallel simulations. In some embodiments, the simulation tasks are prioritized across the resources that are available. For example, the scenario explorer 248 may determine the scenarios that of a scenario matrix that are most likely to provide information related to the inbound task. By prioritizing simulations, it is possible that a path (e.g., branch, etc.) along a selection tree or other optimization algorithm may be stopped based on information found after execution of the higher priority simulations.

Computational resources may be reallocated by the resource allocator 242 if needed (e.g., for timely completion of the simulations included in the scenario matrix). Simulations may then be performed. For example, the environments may be initialized (e.g., the simulations started). The simulation engine 244 may monitor simulation progress. For example, the simulation engine 244 may request periodic updates from the ABM computer cluster 180 via the message queue 178 or subscribe to milestones (e.g., request an update each time 1% or another portion of the simulation or scenario matrix of simulations is complete). If all the simulations are not complete, resources may be reallocated, for example, simulations managed by another of the one or more ABM enhanced agents 200 may have completed freeing additional computational resources for the agent-based model simulations. If the simulation is complete the results may be collected and output.

Referring back to the flow 420, the scenario explorer 248 may analyze the outcomes (e.g., results, etc.) of the one or more executed simulations and determine whether more scenarios should be performed (e.g., whether to generate another scenario matrix), repeating the previous steps. If a stopping criterion is met or the scenario explorer 248 otherwise determines that no additional simulations are necessary, scenarios may be ranked, for example, to identify critical factors and/or generate a scenario report. The scenario report may include tabular, text-based, or graphical information. For example, in some embodiments, the flow 420 includes requesting the one or more external language models 106 to perform analysis of the results (e.g., identify patterns in the critical factors, generate plots, etc.) or generate code that is configured to repeatedly perform the analysis for different scenarios.

### Results Processing

In FIGS. 3 and 4A the one or more ABM enhanced agents 200 are shown to include a cognitive integrator 270, a results synthesizer 280, and an output generator 232 to process outputs from the agent-based model simulation and respond to the inbound task. According to some embodiments, the cognitive integrator 270 receives results from the simulation manager 240. The cognitive integrator 270 uses the results to generate a summary of results that can be incorporated into the knowledge base 292. For example, results may be tabular, name-value pairs, and/or structured text (e.g., JSON, etc.) or unstructured text (e.g., natural language summaries from the one or more external language models 106). The results and/or the summaries from the cognitive integrator 270 may be used by the results synthesizer 280 to generate insight related to the agent-based model simulation. For example, additional text may be generated and stored in the knowledge base 292. Insight may include processed forms of the results such as trends, optimal values, and/or suggestions, and may relate to the inbound task. Finally, with the agent-based model simulations complete, the output generator 232 may use the knowledge generated and stored in the knowledge base 292 to generate an output in response to the inbound task.

In some embodiments, the cognitive integrator 270 generates summaries of the simulation results using the one or more external language models 106. Summaries may be generated using any of the intermediate insights generated by the scenario explorer 248. For example, the trends, key factors, and/or scenario reports generated by the scenario explorer 248 during execution of a scenario matrix for an agent-based model simulation may be provided to the cognitive integrator 270 for summarization.

The cognitive integrator 270 may be configured to determine the portions of the simulations results (e.g., from which scenario matrices, etc.) that should be included in the summary and integrated within the knowledge base 292. In some embodiments, the cognitive integrator 270 is configured to determine whether the plurality of outputs conflict with the knowledge base. For example, the cognitive integrator 270 may compare a first trend from the plurality of outputs with a second trend indicated in the knowledge base. The comparison may be performed based on the numerical value of the trend (e.g., a gradient). In some embodiments, the cognitive integrator 270 may perform a statistical comparison (e.g., a hypothesis test) to determine whether the trends indicated in the knowledge base are significantly different than trends indicated by the previous results. Non-statistics based tests may also be performed, for example, based on the direction of a trend (e.g., whether an outcome of the simulation has a positive correlation with an input variable or has a negative correlation with an input variable.)

The cognitive integrator 270 may generate results for the knowledge base 292 in multiple forms. The cognitive integrator 270 may generate structured text (e.g., JSON, XML, etc.). Structured text, for example, may indicate a hierarchical relationship between results (e.g., outcomes for various agents, outcomes for the whole simulation, etc.). The relationship may also include name-value pairs to indicate the variable that an outcome value of the simulation is for. The cognitive integrator 270 may generate results for a relational or graph-based database. Additionally, results may be generated in tabular form or in natural language. In some embodiments, a combination of several types of storage is used to facilitate processing by multiple algorithms.

In some embodiments, the cognitive integrator 270 may determine whether the plurality of outputs conflict with the knowledge base by performing a semantic comparison. For example, text from the scenario reports and/or results summaries may be compared with the text already stored in the knowledge base 292 related to the outcome and/or results of previous agent-based model simulations.

In some embodiments, the cognitive integrator 270 is configured to resolve conflicting information between the knowledge base 292 and the current results. For example, the cognitive integrator 270 may determine a reason or root cause for the conflicting results. The cognitive integrator 270 may determine the results conflict because previous results were performed earlier and other variables have since changed. The cognitive integrator 270 may determine that the conflict occurred due to an inaccuracy in the simulation. For example, the simulation may have had low resolution, an incorrect number of agents, incorrect variable ranges, etc.

The cognitive integrator 270 may resolve a conflict between the knowledge base 292 and the latest simulation results. In some embodiments, the cognitive integrator 270 is configured to remove (e.g., delete, etc.) the conflicting information from the knowledge base 292. For example, removal may be appropriate where the conditions and results are expected to change periodically and therefore the latest simulation results are likely correct. In some embodiments, the cognitive integrator 270 is configured to cause the simulation manager 240 to rerun the agent-based model simulation with updated values for the one or more simulation properties in response to determining the outputs (e.g., results) conflict with the knowledge base. For example, the time resolution may be increased to determine whether the accuracy of the simulation was low. As another example, the cognitive integrator 270 may provide small changes to the simulation parameters (e.g., agent rules, number of agents, etc.), for example, to determine if the uncertainty in the outcome was high. After a rerun with different parameters, if the cognitive integrator 270 determines that the results are sensitive to initial conditions or otherwise have uncertainty, the cognitive integrator 270 may incorporate the finding of uncertainty into the knowledge base 292.

In some embodiments, the cognitive integrator 270 is configured to resolve a conflict by better aligning the agent-based model simulation with a real-world system the agent-based model simulation represents. For example, the cognitive integrator 270 may request execution of the agent-based model simulation starting at multiple past initial conditions and compare the simulation results to actual measurements from the real-world system. The cognitive integrator 270 may be configured to adjust parameters such that the agent-based model simulation aligns (coincides, etc.) with the measurements from the real-world system. For example, the cognitive integrator 270 may request a simulation from the same initial condition as the past state of the real-world system, execute the simulation forward in time, and compare the trajectory of the simulation to the trajectory measured for the real-world system. The cognitive integrator 270 may use a sum of squared error, sum of absolute error or similar objective function in order to perform the comparison between the simulation and the real-world data and to determine changes to the simulation properties (e.g., parameters, variables, etc.) in order to reduce or otherwise improve the objective function.

FIG. 4D shows flow of operations 440 for incorporating the results of simulations into the knowledge base 292 according to some embodiments. For example, the flow 440 may be performed by the cognitive integrator 270 after simulations have been performed. The flow 440 may begin after receiving the model outcomes (e.g., results, output, etc.) from the simulation environment 260 and/or the simulation manager 240. The cognitive integrator 270 may extract key insights, for example, the insight may include key simulation parameters, trends (e.g., related to how an outcome changes with respect to the input), a best or improved value for a key simulation parameter, etc. After the insight has been extracted, the insight may be compared to the existing knowledge base to determine if the current results are in conflict with the existing information.

If there are conflicts, the conflicts may be resolved. For example, conflict resolution may include determining a root cause or reason for the conflict. Conflict resolution may include removing old information or rerunning the simulation. Conflict resolution may include rerunning the simulation to incorporate a higher resolution (e.g., temporal resolution) or other accuracy increases in order to improve results. Conflict resolution may include rerunning a simulation with updated properties (e.g., parameters, variables, etc.), for example, to improve correlation between the agent-based model simulation and the real-world system that it represents. For example, the cognitive integrator 270 may perform a procedure such as system identification in order to determine appropriate properties.

If no conflicts are identified or the conflicts have already been resolved, the cognitive integrator 270 may update the knowledge base 292. The cognitive integrator 270 may generate information for the knowledge base 292 in a variety of forms including tabular form, name-value pairs, structured text, unstructured text, etc. In some embodiments, the cognitive integrator 270 may tag the new insight. For example, the tags may indicate that the information is new, the type of simulation that was performed to generate the information, the real-world system that is represented by the agent-based model simulation for which the results were generated, etc. Associative links may be updated. For example, the links may be maintained between the entries in the knowledge base 292 and the model (e.g., in the model library 294) and/or the real-world system associated with the information. Finally, the cognitive integrator 270 may prune any outdated information (e.g., based on a recency threshold).

FIG. 4D also shows a flow of operations 450 for integrating insight into the one or more ABM enhanced agents 200 decision making process and/or the output generator 232 according to some embodiments. The flow 450, for example, may be performed by the results synthesizer 280. The results synthesizer 280 may receive model outcomes and summary knowledge generated by the cognitive integrator 270 and integrated into the knowledge base 292 and integrate insight generated within the agents decision process.

In some embodiments, the results synthesizer 280 is configured to identify patterns across multiple models. For example, the results synthesizer 280 may generate holistic insight based on the outcomes of multiple agent-based model simulations that have already been validated for conflicts by the cognitive integrator 270. The results synthesizer 280 may be configured to identify causal relationships. For example, the results synthesizer 280 may identify causal relationships between at least one outcome (e.g., output, etc.) from the simulation model and values of one or more simulation properties.

In some embodiments, the results synthesizer 280 is configured to execute a causal analysis algorithm to determine causality. For example, the results synthesizer 280 may perform the Peter-Clark (Spirtes-Glymour) analysis. The results synthesizer 280 may generate a graph with nodes that represent variables. The results synthesizer 280 may then remove edges between the nodes based on tests for statistical independence. For example, if the test indicates that the edge may be independent the connection between the nodes may be removed. After independent edges have been removed, the results synthesizer 280 may orient (give direction to) the remaining edges (e.g., based on logical rules such as avoiding causal cycles) to generate a directed acyclic graph (DAG).

In some embodiments, the results synthesizer 280 may perform hypothesis testing. For example, the results synthesizer 280 may be configured to generate hypotheses and then evaluate the strength of each hypothesis. In some embodiments, the results synthesizer 280 uses a language model (e.g., the one or more external language models 106) in order to generate the hypothesis. The results synthesizer 280 may be configured to test the hypotheses generated by the language model using a statistical test. The results synthesizer 280 may include a number of hypothesis templates that can be used against various variables (e.g., outcome variables and/or input parameters) of the agent-based model simulation. In some embodiments, the results synthesizer 280 may prompt the one or more external language models 106 with a description of the hypothesis tests, data and/or text from the knowledge base 292 and/or recent simulation results, and a request to identify the hypothesis to test. The hypothesis strength of each test identified by the one or more external language models 106 may then be evaluated based on the test-statistic (e.g., by its p-value). In some embodiments, the hypothesis tests identified by the results synthesizer 280 may be used to perform the causal inference.

In some embodiments, the results synthesizer 280 generates (e.g., synthesizes) high-level insights based on simulation outcomes. For example, the results synthesizer 280 may generate insight for multiple models. The results synthesizer 280 may also be configured to assess the confidence level of the high-level insight. The results synthesizer 280 may include high-level insight related to high confidence levels in the output of the results synthesizer 280. The results synthesizer 280 may generate a natural language summary (e.g., using the one or more external language models 106) of the causal relationships and high-level insight generated by the results synthesizer 280. The results synthesizer 280 may also integrate the information (e.g., the summary, and/or the results of the hypothesis tests, the causal inference techniques, etc.) with the decision making process of the one or more ABM enhanced agents 200.

Referring again to FIG. 4A, the output generator 232 is shown to have access to the knowledge base 292, the inbound task, simulation results, and the insights generated by the results synthesizer 280 and/or cognitive integrator 270. The output generator 232 may respond to the inbound request by prompting the one or more external language models 106 using the information from the knowledge base 292 (e.g., including information from the cognitive integrator 270 and/or the results synthesizer 280), thereby providing more accurate responses and avoiding hallucinations when questions are asked regarding real-world systems about which the one or more external language models 106 are queried.

In some embodiments, the output generator 232 is configured to generate an action signal in response to the inbound task. Action signals may be configured to initiate an action in an external system or one or more ABM enhanced agents 200. The action signals may be communicated to the one or more remote systems 104 and/or one or more client devices 102 over the network 120. In some embodiments, the action signal is communicated to an application programming interface (API) within the one or more remote systems 104 and/or the one or more client devices 102. After the action signal is received by the API or other communication interface of the one or more remote systems 104 and the one or more client devices 102 the action may be initiated. Action signals may cause the one or more remote systems 104 and/or the one or more client devices 102 to perform an action in response to the inbound task. For example, the output generator 232 may generate an action signal that modifies a parameter of the real-world system represented by the agent-based model simulation according to a parameter of the simulation shown to have desirable properties (e.g., causing improved or optimal results, etc.).

Non-limiting example action signals include signals to modify parameters of a real-world system for improved results indicated by the agent-based model simulation (e.g., communicating the parameters to a control system, a database, API, etc.), generate a calendar entry indicated by the agent-based model simulation, send a notification or reminder (e.g., by push notifications, text, and/or email) to perform an action indicated by (e.g., based on) the agent-based model simulation, generate a report indicating improvement process improvements recommended using the agent-based model simulation, and generate a purchase order for equipment and/or software indicated by the agent-based model simulation.

### Operational Flow

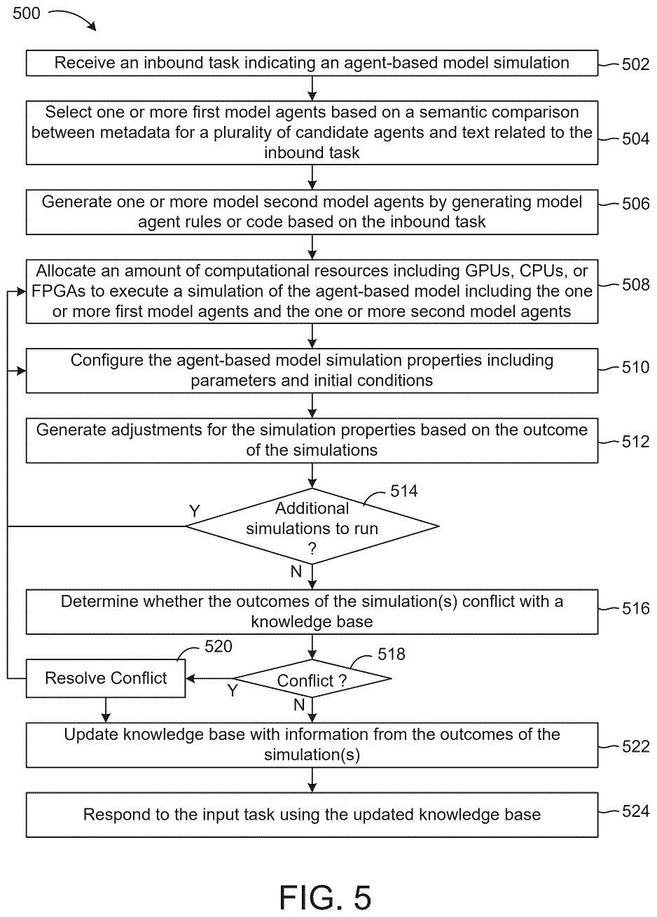

FIG. 5 shows flow of operations 500 for responding to an inbound task with information from an agent-based model simulation according to some embodiments. The flow 500 may be performed by the one or more ABM enhanced agents 200, for example, using the other systems and/or components of the ABM enhanced response system 100.

In some embodiments, the flow 500 includes receiving an inbound task indicating an agent-based model simulation in the operation 502. Some tasks may be responded to directly using a one or more external language models 106. In addition, some tasks may be related to a real-world system for which simulations have already been performed and can be used to determine an accurate response. Some tasks may indicate a new agent-based model simulation. The operation 502 may include determining whether the inbound task indicates an agent-based model simulation, for example, whether a response would be improved by access to results from an agent-based model simulation related to the inbound task. For example, the task may be received by the one or more ABM enhanced agents 200 and communicated to the task manager 222. A portion of the operation 502 may be performed by the task manager 222. Additionally, any operation or functionality described as performed by the task manager 222 may be included, in some embodiments, in the operation 502.

The flow 500 may include selecting one or more first model agents based on a semantic comparison between metadata for a plurality of candidate agents (e.g., model agents) and text related to the inbound task in operation 504. The operation 504 may include prompting a language model with information (e.g., text, etc.) related to one or more of the candidate agents (e.g., from the metadata) and the inbound task. The prompt may include a request for the language model to select (e.g., identify, etc.) the model agents that can represent real-world entities indicated by the inbound task. The operation 504 may include performing the semantic comparison based on a comparison of vector embeddings. For example, the operation 504 may include generating vector embeddings for text related to the metadata of the candidate model agents and a vector embedding for text related to the inbound task. The operation 504 may include comparing the vector embeddings with a distance metric (e.g., the cosine distance) and selecting the candidate agents that have a corresponding vector embedding that satisfies a distance criterion with the vector embedding related to the inbound task. For example, the operation 504 may include evaluating the distance for each candidate agent against a threshold distance or selecting a set number of candidate agents such as the candidate agents with the lowest distance.

In some embodiments, the operation 504 also includes generating a number of agents for each of the candidate agents selected. For example, the inbound task may be analyzed for a complexity or another indication of the number of model agents that are appropriate to respond to the inbound task.

The flow 500 may include generating one or more second model agents by generating model agent rules or code based on the inbound task in operation 506. For example, if certain portions of the inbound task do not correspond to a selected candidate agent, a model agent may be generated. Generation of a model agent in the operation 506 may be performed similarly to selection of candidate agents (e.g., at a different level of granularity). For example, the operation 506 may include adding rules, interactions, and/or internal states to a model agent template (e.g., an empty or partial constructed model agent). Rules may be selected based on a semantic analysis or generated directly from the inbound task (e.g., based on a semantic comparison). The operations 504 and 506 may be performed by the model generator 226. Additionally, any operation or functionality described as performed by the model generator 226 may, in some embodiments, be included in the operations 504 or 506.

In some embodiments, the flow 500 includes allocating an amount of computational resources including GPUs, CPUs, or FPGAs to execute a simulation of the agent-based model including the one or more first model agents and the one or more second model agents in operation 508. In some embodiments, the complexity analyzer 228 uses a rules-based approach to determine the resource requirements for the execution. For example, each model agent may be associated with a number of CPUs, GPUs, and FPGAs required to execute the model agent, the memory requirements, and the amount of time executing the model agent requires. To determine the proper allocation (e.g., the amount or number of hardware devices), the operation 508 may include totalizing the number of CPUs, GPUs, and FPGAs required to execute the model agent and the memory requirements based on the total number of each type of model agent. Total processing time may be calculated based on the time for each of the model agents and the number of steps (e.g., iterations, time periods, etc.) in the model simulation. For example, by summing the time for each model agent and multiplying by the number of steps.

In some embodiments, the operation 508 includes executing the simulation model or individual model agents thereof to estimate the computation requirements. The operation 508 may include executing a model agent of each type for various hardware configurations and then performing rules-based totalization to determine the total processing time and/or memory requirements for each hardware configuration. The operation 508 may include generating a multidimensional function indicating the expected processing time and/or memory requirements for different hardware allocations. Interpolation may be performed in order to generate the multidimensional function of the total processing time and/or memory as a function of the number or amount of CPUs, GPUs, and FPGAs allocated to the simulation. The operation 508 may include performing an optimization to determine an appropriate model allocation, for example, by generating an objective function and/or constraints that include the cost of the operating the CPUs, GPUs, and FPGAs, the time required to complete the simulation and/or the memory used by the simulation and optimize the objective function subject to the constraints.

After an appropriate amount of hardware has been determined. It can be provisioned (e.g., allocated), for example, from the ABM computer cluster 180. The operation 508 may be performed by the complexity analyzer 228. Additionally, any operation or functionality described as performed by the complexity analyzer 228 may, in some embodiments, be included in the operation 508.

The flow 500 may include configuring the agent-based model simulation properties including parameters and initial conditions in the operation 510. The operation 510 may also include performing the simulations. For example, the simulation properties may be injected into the simulation environment. The simulation may then be propagated forward in time. For example, the operation 510 may include performing state updates for each of the model agents in the agent-based model simulation. The operation 510 may be performed by the simulation engine 244 and/or the dynamic model configurator 246. Additionally, any operation or functionality described as performed by the simulation engine 244 and/or the dynamic model configurator 246. may, in some embodiments, be included in the operation 510.

Adjustments for the simulation properties may be generated based on the outcome of the simulations in the operation 512. For example, the operation 512 may determine a number of scenarios. A scenario for example, may include a number of parameters for the model agents or other changes for the simulation including initial conditions, model agent rules, a number of model agents, etc. In some embodiments, the operation 512 generates a scenario matrix for a number of simulations that can be performed in parallel. The scenarios generated may be based on the results of a previous simulation. For example, the operation 512 may include performing an optimization or similar algorithm to continually update the simulation properties until the results reach a desired goal and/or stopping condition. The operation 512 may be performed by the scenario explorer 248. Additionally, any operation or functionality described as performed by the scenario explorer 248 may, in some embodiments, be included in the operation 512.

At the decision 514 the flow 500 may determine whether additional simulations are to be performed. For example, if no adjustments are generated by the operation 512 or another stopping criterion is met, the flow 500 may continue to the operation 516. If additional simulation properties are determined to be executed, then the flow 500 may continue back to either operation 510 or the operation 508 depending on whether the hardware is to be reallocated (e.g., because additional resources have become available.).

After all the simulations have been completed, the flow 500 may include determining whether the outcomes of the simulation(s) conflict with a knowledge base in operation 516. The operation 516 may include recognizing key variables (e.g., parameters, etc.) related to the simulation. The operation 516 may also include determining trends related to the outcomes of the simulations. A trend may refer to an indication of the change in an output of the simulation in response to an amount of change in the input. For example, the trend may refer to an expected gradient of the outcomes of the simulation. After trends have been established, they can be compared to existing trends in the knowledge base in the operation 516. For example, the trends may be compared by a language model and/or trends may be compared by a statistical analysis (e.g., hypothesis test, etc.). At decision 518, if the latest simulation results conflict (e.g., have different trends) with the existing knowledge base, the flow 500 may be directed towards operation 520 to resolve the conflict. The operation 520 may include generating a root cause for the conflict. Based on the root cause, previous information may be removed from the knowledge base and/or additional simulations may be requested (e.g., with differing resolution, or with parameters adjusted to better align with the real-world system represented by the agent-based model simulation). After the conflict has been resolved, the knowledge base may be updated with information from the outcomes of the one or more simulations in the operation 522. For example, the operation may include generating database entries and/or structured or unstructured text to be included in the knowledge base. The operations 516-522 may be performed by the cognitive integrator 270. Additionally, any operation or functionality described as performed by the cognitive integrator 270 may, in some embodiments, be included in the operations 516-522.

The flow 500 may include responding to the inbound task using the updated knowledge base in operation 524. For some tasks the operation 524 includes providing a response from a language model. For example, the operation 524 may include prompting the language model with text or other content from the inbound task and the updated knowledge base including the latest results from the simulation executed in the operation 510. To facilitate prompting the language model the knowledge base may be broken into portions that can be independently retrieved and provided to the language model. For example, the operation 524 may include performing a retrieval augmented generation (RAG)-based approach to including information with the operation 524. For example, the operation 524 may include retrieving relevant portions of the knowledge base based on a semantic search (e.g., comparison of embedding vectors), keyword search, or regular expression and providing those portions to the language model with a prompt.

For some tasks the operation 524 may include generating an action signal based on the updated knowledge base. For example, the operation 524 may include generating an action signal configured to initiate an action in an external system or the one or more ABM enhanced agents 200. The operation 524 may include communicating the action signal to the one or more remote systems 104 and/or one or more client devices 102 (e.g., to an API thereof) over the network 120. Receipt of the action signal may cause the one or more remote systems 104 and/or the one or more client devices 102 to perform an action in response to the inbound task. In some embodiments, the action signal of operation 524 modifies a parameter of the real-world system represented by the agent-based model simulation according to a parameter of the simulation shown to have desirable properties (e.g., causing improved or optimal results, etc.). For example, the action signal may be communicated to a control system to affect operation of another system (e.g., a car, manufacturing process, building). The operation 524 may be performed by the output generator 232. Additionally, any operation or functionality described as performed by the output generator 232 may, in some embodiments, be included in the operation 524.

### Configurations and Exemplary Embodiments

In some embodiments, the ABM enhanced response system 100 provides an adaptive resource allocation system for organizations utilizing agent-based modeling (ABM) technology. For example, the ABM enhanced response system 100 may employ ABM-assisted agents to optimize distribution of computational and operational resources across multiple departments and projects. The ABM enhanced response system 100 may be configured to balance competing objectives, respond dynamically to environmental changes, and generate recommendations that support strategic organizational goals. Through continuous analysis and simulation, the ABM enhanced response system 100 may adaptively reallocate resources in response to varying conditions, enabling improved efficiency and alignment with evolving project priorities.

In some embodiments, the one or more ABM enhanced agents 200 continuously monitors current resource utilization across all departments, tracks incoming project requests and their priorities, and considers external factors that might impact resource availability or project timelines. The one or more ABM enhanced agents 200 may identify significant changes, such as a sudden increase in high-priority projects combined with unexpected resource constraints.

In some embodiments, the one or more ABM enhanced agents 200 ABM Generator constructs multiple models, including a resource allocation model that simulates the flow of resources throughout an organization, a project timeline model that predicts completion times and dependencies, an external factor model that assesses potential impacts on resource availability, and a performance model that evaluates the outcomes of different allocation strategies.

In some embodiments, the one or more ABM enhanced agents 200 adjusts the agent-based model simulation in real time, increasing the granularity of the resource allocation model for constrained resources and updating project timeline parameters based on the latest priority assessments.

In some embodiments, the one or more ABM enhanced agents 200 concurrently runs the agent-based model simulation to simulate various resource allocation scenarios for the upcoming quarter, modeling potential impacts on project timelines and overall organizational performance.

In some embodiments, the one or more ABM enhanced agents 200 generates and evaluates multiple strategies, such as reallocating resources from lower-priority projects, bringing in temporary external resources, adjusting project timelines and deliverables, or implementing new efficiency measures to make the most of existing resources.

In some embodiments, the one or more ABM enhanced agents 200 combines simulation results with historical data related to past resource allocation decisions and the outcomes, aligns with the organization's strategic goals and priorities, and incorporates best practices in resource management from relevant industries.

In some embodiments, in some embodiments, the one or more ABM enhanced agents 200 analyzes the integrated data and recommends an approach. For example, implementing a dynamic resource reallocation plan that shifts a portion of resources from lower-priority projects, bringing in specialized external resources for high-priority tasks, adjusting timelines for non-critical projects, and rolling out targeted efficiency training to enhance resource utilization.

In some embodiments, the one or more ABM enhanced agents 200 initiates the recommended changes by sending updated resource allocation plans to project managers, assigning HR to acquire necessary temporary resources, distributing training modules to relevant teams, and continuously monitoring the effects of these changes to make further adjustments as needed.

The adaptive resource allocation system may leverage agent-based modeling to efficiently prioritize and distribute resources across an organization, ensuring high-priority projects are completed on time while minimizing delays for lower-priority initiatives. The system may dynamically integrate and analyze multiple models, incorporate historical data for continuous learning, and adjust strategies in real time to enhance overall efficiency and responsiveness. This scalable approach demonstrates predictive capabilities, balances competing objectives, and is applicable to a wide range of fields that require optimal management of limited resources.

In some embodiments, the ABM enhanced response system 100 provides an adaptive drug candidate selection platform for pharmaceutical research teams utilizing agent-based modeling (ABM) technology. For example, the ABM enhanced response system 100 may employ ABM-assisted agents to simulate cellular responses to multiple drug candidates targeting a specific signaling pathway involved in autoimmune diseases. The ABM enhanced response system 100 is configured to predict efficacy, assess safety profiles, and identify emergent behaviors prior to costly in vivo experiments, thereby streamlining the drug discovery process.

In some embodiments, the one or more ABM enhanced agents 200 continuously assesses known cellular components in the target pathway, evaluates initial data from fifty drug candidates, integrates in vitro assay results, and manages computational resources to run complex tissue simulations.

In some embodiments, the one or more ABM enhanced agents 200 ABM Generator constructs sophisticated agent-based models representing individual cells, intracellular signaling processes, drug molecules as interacting agents, and the extracellular environment as a scalable three-dimensional space.

In some embodiments, the one or more ABM enhanced agents 200 dynamically adjusts agent-based model parameters in real time, updating models based on new cell-to-cell communication findings and drug-target binding kinetics as experimental and literature data become available.

In some embodiments, the one or more ABM enhanced agents 200 runs concurrent simulation scenarios simulating cellular responses to various drug candidates under multiple concentrations, models drug distribution and uptake in a tissue environment, and projects long-term effects on cell populations over simulated periods.

In some embodiments, the one or more ABM enhanced agents 200 generates and evaluates multiple strategies, assessing drug efficacy in suppressing aberrant signaling, analyzing potential off-target effects, investigating emergent cellular behaviors, and modeling the likelihood of drug resistance development.

In some embodiments, the one or more ABM enhanced agents 200 incorporates simulation outcomes with historical data from prior drug classes, recent publications regarding the target pathway, and domain expert knowledge on autoimmune disease progression for more accurate predictions.

In some embodiments, the one or more ABM enhanced agents 200 synthesizes insights from integrated models and data, recommending prioritization of top drug candidates, suggesting dosing regimens derived from cellular uptake simulations, and identifying biomarkers for early resistance detection. The system also designs targeted in vitro experiments to validate simulation outputs.

In some embodiments, the one or more ABM enhanced agents 200 initiates the recommended course of action by launching detailed in vitro studies on selected candidates, developing new assays for proposed biomarkers, and continuously refining ABMs with incoming experimental data.

The adaptive drug candidate selection platform may leverage agent-based modeling to reduce candidate selection time, uncover emergent benefits and risks, and validate critical findings through high-fidelity simulation and experimentation. By capturing multi-scale interactions and enabling hypothesis-driven research, the system improves predictive power, refines models iteratively, and facilitates resource-efficient drug development workflows. This scalable and integrative approach demonstrates its value in advancing drug discovery, supporting optimal candidate selection, and accelerating the path to clinical innovation.

In some embodiments, the ABM enhanced response system 100 provides an adaptive AI personal assistant platform utilizing agent-based modeling (ABM) technology to manage a user's daily life, social interactions, and personal preferences. For example, the ABM enhanced response system 100 may generate agent-based model simulations including complex and dynamic aspects such as schedules, relationships, energy levels, and decision tradeoffs by employing internal ABM-assisted agents, enabling the AI to deliver highly personalized and context-sensitive recommendations and support throughout daily activities.

In some embodiments, the one or more ABM enhanced agents 200 maintain a continuously evolving agent-based model wherein the user is represented as a central agent with dynamic goals, energy patterns, and shifting preferences. Contacts may be modeled as agents with relational strengths, communication histories, and availability patterns, while tasks, events, and locations are characterized as agents that interact via priorities, dependencies, travel times, and other contextual influences.

In some embodiments, the one or more ABM enhanced agents 200 perform daily simulations each morning, optimizing the user's schedule based on task priorities, predicted energy levels, and anticipated needs, while identifying potential conflicts and opportunities to increase efficiency throughout the day.

In some embodiments, the one or more ABM enhanced agents 200 utilize social interaction modeling to simulate conversation flows, recommend optimal times for communication with different contacts, and suggest personalized communication styles grounded in past interactions and current context.

In some embodiments, the one or more ABM enhanced agents 200 adaptively learn and update their internal models based on user responses to schedule changes and approvals, social interaction outcomes, routine modifications, and new preferences that emerge over time.

In some embodiments, the one or more ABM enhanced agents 200 provide multi-contextual decision support by running counterfactual ABM scenarios that evaluate the impact of choices on work, social, and personal life, predict long-term outcomes, and highlight subtle factors influencing possible results.

In some embodiments, the one or more ABM enhanced agents 200 refine real-time recommendations and explanations by monitoring ongoing events, adjusting to unexpected developments, and referencing internal ABM structures for cognitive transparency in user interactions.

The AI personal assistant platform may leverage agent-based modeling to reason about abstract concepts like energy, motivation, and relationships, uncover hidden patterns in the user's daily life, and dynamically support nuanced decision-making and behavioral adaptation. Through holistic and transparent multi-dimensional analysis, the system delivers intuitive, context-aware assistance that continuously evolves with the user's needs, enhancing everyday scheduling, communication, and decision support. This approach demonstrates the power and versatility of ABMs for augmenting AI-enabled personal companions capable of navigating and optimizing the complexities of human life. In some embodiments, the cognitive system is configured with a model library that implements version control for tracking the evolution of internal models over time. This allows for transparent record-keeping of changes to agent-based models, supporting reproducibility and informed model refinement.

An embodiment relates to a cognitive system for enhancing ai agent reasoning capabilities. the cognitive system includes an ABM generator for dynamically creating agent-based models, a model library for storing and categorizing ABM templates and components, a task analyzer for interpreting current tasks and determining relevant ABM types, a dynamic model configurator for real-time adjustment of ABM parameters, a simulation engine for managing concurrent ABM simulations, a scenario explorer for generating and comparing alternative scenarios, a cognitive integration layer for integrating model outcomes with existing knowledge, and an insight synthesizer for analyzing patterns and generating high-level insights.

In some embodiments, the cognitive system is configured with a modular design pattern for rapid internal model generation and modification.

In some embodiments, the task analyzer employs machine learning techniques to determine appropriate internal ABM types and complexity levels.

In some embodiments, the cognitive system includes a dynamic model configurator that supports on-the-fly modification of agent behaviors and environmental rules within active agent-based models. This enables the AI agent to quickly adapt simulations in response to evolving requirements or new information.

In some embodiments, the cognitive system includes a simulation engine that allocates computational resources according to the priority and complexity of the active tasks. The simulation engine may optimize performance and ensure that more critical or complex simulations receive appropriate attention.

In some embodiments, the cognitive system includes an integration layer that utilizes agent-based models as a form of active, manipulable working memory, allowing the AI agent to maintain and adapt internal representations as reasoning progresses.

In some embodiments, the cognitive system is configured to use a wide range of agent-based model types, including simple, complex, adaptive, hybrid, data-driven, multi-scale, and interactive models, thereby supporting flexible and comprehensive cognitive processing.

In some embodiments, the scenario explorer employs a Monte Carlo tree search algorithm to efficiently traverse large possibility spaces, enabling rapid and robust comparison of alternative reasoning scenarios.

In some embodiments, the cognitive system includes a mechanism for translating internal agent-based model structures and reasoning outcomes into natural language explanations, supporting transparent and explainable AI.

In some embodiments, the insight synthesizer to employ causal inference techniques, identifying potential cause-effect relationships both within individual models and across multiple internal models.

An embodiment relates to a method for enhancing AI agent reasoning using dynamic agent-based modeling. The method may include analyzing the current task and available cognitive resources, selecting appropriate ABM types and complexity levels, generating or retrieving models from an internal library, configuring models for simulation within the agent's cognitive space, exploring multiple scenarios by modifying internal parameters, integrating model outcomes with the agent's existing knowledge, and synthesizing insights to facilitate conceptual learning.

In some embodiments, the method further includes dynamically adjusting the complexity of internal models in real time, based on the requirements of the current task and available cognitive resources.

In some embodiments, the method is designed to utilize multiple types of agent-based models simultaneously for complex reasoning tasks, supporting multi-faceted problem-solving and integrative analysis.

In some embodiments, the method further comprises continuous updates and evolution of internal models, using new experiences, data, and outcomes to improve future predictions and recommendations.

In some embodiments, the method further includes cross-validation of results across different internal model types to improve reasoning accuracy and ensure consistency in generated insights.

Some embodiments relate to a non-transitory computer-readable medium, storing instructions that, when executed by a processor, enable the method described above for enhancing AI agent reasoning through dynamic agent-based modeling.

In some embodiments, generating or retrieving models consists of creating new agent-based model components in real time using a domain-specific language when existing components are insufficient, thereby expanding the system's modeling capabilities on demand.

In some embodiments, a system for enhancing AI agent cognitive capabilities is provided, comprising the cognitive system integrated within an AI agent's core reasoning architecture for seamless operation.

In some embodiments, this integrated cognitive system allows the AI agent to perform general problem solving, adaptive learning in dynamic environments, complex system understanding, social interaction modeling, creative ideation, multi-domain knowledge integration, and internal state representation for explainable AI.

One aspect of the present disclosure relates to a system including one or more processing circuits configured to receive an inbound task related to a real-world system. The one or more processing circuits are also configured to select one or more agents for an agent-based model simulation of the real-world system based on a semantic comparison between metadata for a plurality of candidate agents and an input task. Each of the one or more agents selected representing an entity of the real-world system. The one or more processing circuits are also configured to generate a plurality of outputs by executing the agent-based model simulation including the one or more agents selected. Each output of the plurality of outputs corresponding to respective values for one or more simulation properties. The one or more processing circuits are also configured to update a knowledge base for storing information related to the real-world system based on the plurality of outputs for the respective values of the one or more simulation properties and respond to the input task by prompting one or more language model with the updated knowledge base.

In some embodiments, the one or more processing circuits are further configured to determine an amount of computational resources to be used to execute the agent-based model simulation based on the one or more agents selected and allocate the amount of the computational resources to perform the agent-based model simulation.

In some embodiments, the amount of the computational resources includes an amount of graphics processing units, central processing units, and field programmable gate array devices and the one or more processing circuits are configured to allocate the amount of graphics processing units, central processing units, and field programmable gate array devices.

In some embodiments, the one or more processing circuits are configured to determine the amount of the computational resources according to an objective function including at least one of a cost to execute the agent-based model simulation or a time required to execute the agent-based model simulation.

In some embodiments, the one or more processing circuits are further configured to adjust values for the one or more simulation properties for another agent-based model simulation based on the plurality of outputs.

In some embodiments, the one or more processing circuits are configured to adjust the values for the one or more simulation properties using a Monte Carlo tree search algorithm.

In some embodiments, the one or more processing circuits are further configured to determine whether the plurality of outputs conflict with the knowledge base by comparing a first trend from the plurality of outputs with a second trend indicated in the knowledge base.

In some embodiments, the one or more processing circuits are further configured to rerun the agent-based model simulation with updated values for the one or more simulation properties in response to determining the plurality of outputs conflict with the knowledge base.

In some embodiments, the one or more processing circuits are further configured to update the agent-based model simulation based on current information from the real-world system.

In some embodiments, the one or more processing circuits are further configured to store a log of updates to the agent-based model simulation.

In some embodiments, the one or more processing circuits are further configured to generate a second agent-based model simulation by selecting one or more alternative agents and determine whether the plurality of outputs and a plurality of second outputs from the second agent-based model simulation conflict.

In some embodiments, the one or more processing circuits are further configured to identify causal relationships between at least one of the plurality of outputs and the respective values of the one or more simulation properties.

In some embodiments, the metadata for a respective agent of the plurality of candidate agents includes at least one of a name of the respective agent, a description of the respective agent, a description of the entity represented by the respective agent, or a description of a set of rules followed by the respective agent within the agent-based model simulation.

In some embodiments, the one or more simulation properties include at least one of a parameter for a rule of an agent of the one or more agents selected, a number of agents included in the agent-based model simulation, or an initial condition of the agent-based model simulation.

Another aspect relates to a system including one or more processing circuits configured to operate an artificial intelligence-based agent for responding to tasks using a knowledge base for storing information related to a real-world system. The artificial intelligence-based agent is configured to receive an inbound task related to the real-world system. The artificial intelligence-based agent is also configured to generate an agent-based model simulation of the real-world system by selecting a plurality of model agents based on a semantic comparison between metadata for a plurality of candidate agents and text related to the inbound task. Each of the plurality of model agents selected representing an entity of the real-world system. The artificial intelligence-based agent is also configured to execute the agent-based model simulation to generate a first output and adjust one or more properties of the agent-based model simulation based on the inbound task and the first output. The artificial intelligence-based agent is also configured to add, to the knowledge base, a summary of the first output and a second output of the adjusted agent-based simulation and perform an automated action based on the summary responsive to the inbound task.

In some embodiments, the artificial intelligence-based agent is further configured to allocate an amount of computational resources to be used to execute the agent-based model simulation according to an objective function including at least one of a cost to execute the agent-based model simulation or a time required to execute the agent-based model simulation, wherein the computational resources include at least one of graphics processing units, central processing units, or field programmable gate array devices.

In some embodiments, the artificial intelligence-based agent is further configured to determine whether the first output or the second output conflict with the knowledge base by comparing a first trend generated using at least the first output and the second output with a second trend indicated in the knowledge base and responsive to a determination that the first output or the second output conflict with the knowledge base, rerun the agent-based model simulation with updated values for the one or more properties.

In some embodiments, the artificial intelligence-based agent is further configured to update the agent-based model simulation based on current information from a real-world system represented by the agent-based model simulation.

In some embodiments, the automated action includes at least one of update a user interface with a recommendation based on the summary, the recommendation determined to cause a real-world system represented by the agent-based model simulation to exhibit behavior observed in the agent-based model simulation, generate an electronic mail communicating a recommendation based on the summary, the recommendation determined to cause the real-world system represented by the agent-based model simulation to exhibit behavior observed in the agent-based model simulation, and generate an input to an application interface based on the summary, the input configured to cause the real-world system represented by the agent-based model simulation to exhibit behavior observed in the agent-based model simulation.

Another aspect relates to a method that includes receiving, by one or more processors, an inbound task related to a real-world system. The method also includes selecting, by the one or more processors, one or more agents for an agent-based model simulation of the real-world system based on a semantic comparison between metadata for a plurality of candidate agents and an input task, each of the one or more agents selected representing an entity of the real-world system. The method also includes generating, by the one or more processors, a plurality of outputs by executing the agent-based model simulation including the one or more agents selected, each output of the plurality of outputs corresponding to respective values for one or more simulation properties. The method also includes updating, by the one or more processors, a knowledge base for storing information related to the real-world system with a summary of the plurality of outputs for the respective values of the one or more simulation properties and responding, by the one or more processors, to the input task by prompting one or more language model with the updated knowledge base.

It should be understood that no claim element herein is to be construed under the provisions of 35 U.S.C. § 112(f), unless the element is expressly recited using the phrase “means for.”

As used herein, the term “circuit” may include hardware structured to execute the functions described herein. In some implementations, each respective “circuit” may include machine-readable media for configuring the hardware to execute the functions described herein. The circuit may be embodied as one or more circuitry components including, but not limited to, processing circuitry, network interfaces, peripheral devices, input devices, output devices, sensors, etc. In some implementations, a circuit may take the form of one or more analog circuits, electronic circuits (e.g., integrated circuits (IC), discrete circuits, system on a chip (SOC) circuits), telecommunication circuits, hybrid circuits, and any other type of “circuit.” In this regard, the “circuit” may include any type of component for accomplishing or facilitating achievement of the operations described herein. For example, a circuit as described herein may include one or more transistors, logic gates (e.g., NAND, AND, NOR, OR, XOR, NOT, XNOR), resistors, multiplexers, registers, capacitors, inductors, diodes, wiring, and so on.

The “circuit” may also include one or more processors communicatively coupled to one or more memory or memory devices. In this regard, the one or more processors may execute instructions stored in the memory or may execute instructions otherwise accessible to the one or more processors. In some implementations, the one or more processors may be embodied in various ways. The one or more processors may be constructed in a manner sufficient to perform at least the operations described herein. In some implementations, the one or more processors may be shared by multiple circuits (e.g., circuit A and circuit B may comprise or otherwise share the same processor, which, in some example implementations, may execute instructions stored, or otherwise accessed, via different areas of memory). Alternatively or additionally, the one or more processors may be structured to perform or otherwise execute certain operations independent of one or more co-processors.

In other example implementations, two or more processors may be coupled via a bus to enable independent, parallel, pipelined, or multi-threaded instruction execution. Each processor may be implemented as one or more general-purpose processors, ASICs, FPGAs, GPUs, TPUs, digital signal processors (DSPs), or other suitable electronic data processing components structured to execute instructions provided by memory. The one or more processors may take the form of a single core processor, multi-core processor (e.g., a dual core processor, triple core processor, or quad core processor), microprocessor, etc. In some implementations, the one or more processors may be external to the apparatus, for example, the one or more processors may be a remote processor (e.g., a cloud-based processor). Alternatively or additionally, the one or more processors may be internal or local to the apparatus. In this regard, a given circuit or components thereof may be disposed locally (e.g., as part of a local server, a local computing system) or remotely (e.g., as part of a remote server such as a cloud based server). To that end, a “circuit” as described herein may include components that are distributed across one or more locations.

An exemplary system for implementing the overall system or portions of the implementations might include a general purpose computing devices in the form of computers, including a processing unit, a system memory, and a system bus that couples various system components including the system memory to the processing unit. Each memory device may include non-transient volatile storage media, non-volatile storage media, non-transitory storage media (e.g., one or more volatile or non-volatile memories), etc. In some implementations, the non-volatile media may take the form of ROM, flash memory (e.g., flash memory such as NAND, 3D NAND, NOR, 3D NOR), EEPROM, MRAM, magnetic storage, hard discs, optical discs, etc. In other implementations, the volatile storage media may take the form of RAM, TRAM, ZRAM, etc. Combinations of the above are also included within the scope of machine-readable media. In this regard, machine-executable instructions comprise, for example, instructions and data, which cause a general-purpose computer, special purpose computer, or special purpose processing machines to perform a certain function or group of functions. Each respective memory device may be operable to maintain or otherwise store information relating to the operations performed by one or more associated circuits, including processor instructions and related data (e.g., database components, object code components, script components), in accordance with the example implementations described herein.

It should also be noted that the term “input devices,” as described herein, may include any type of input device including, but not limited to, a keyboard, a keypad, a mouse, joystick, or other input devices performing a similar function. Comparatively, the term “output device,” as described herein, may include any type of output device including, but not limited to, a computer monitor, printer, facsimile machine, or other output devices performing a similar function.

It should be noted that although the diagrams herein may show a specific order and composition of method steps, it is understood that the order of these steps may differ from what is depicted. For example, two or more steps may be performed concurrently or with partial concurrence. Also, some method steps that are performed as discrete steps may be combined, steps being performed as a combined step may be separated into discrete steps, the sequence of certain processes may be reversed or otherwise varied, and the nature or number of discrete processes may be altered or varied. The order or sequence of any element or apparatus may be varied or substituted according to alternative implementations. Accordingly, all such modifications are intended to be included within the scope of the present disclosure as defined in the appended claims. Such variations will depend on the machine-readable media and hardware systems chosen and on designer choice. It is understood that all such variations are within the scope of the disclosure. Likewise, software and web implementations of the present disclosure could be accomplished with standard programming techniques with rule-based logic and other logic to accomplish the various database searching steps, correlation steps, comparison steps, and decision steps.

While this specification contains many specific implementation details, these should not be construed as limitations on the scope of any inventions or of what may be claimed, but rather as descriptions of features specific to particular implementations of the systems and methods described herein. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products.

Having now described some illustrative implementations and implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. Acts, elements, and features discussed only in connection with one implementation are not intended to be excluded from a similar role in other implementations.

The phraseology and terminology used herein is for the purpose of description and should not be regarded as limiting. The use of “including,” “comprising,” “having,” “containing,” “involving,” “characterized by,” “characterized in that,” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, 67 or elements to single or plural configurations. References to any act or element being based on any information, act, or element may include implementations where the act or element is based at least in part on any information, act, or element.

Any implementation disclosed herein may be combined with any other implementation, and references to “an implementation,” “some implementations,” “an alternate implementation,” “various implementation,” “one implementation,” or the like are not necessarily mutually exclusive and are intended to indicate that a particular feature, structure, or characteristic described in connection with the implementation may be included in at least one implementation. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms.

Where technical features in the drawings, detailed description or any claim are followed by reference signs, the reference signs have been included for the sole purpose of increasing the intelligibility of the drawings, detailed description, and claims. Accordingly, neither the reference signs nor their absence have any limiting effect on the scope of any claim elements.

The foregoing description of implementations has been presented for purposes of illustration and description. It is not intended to be exhaustive or to limit the disclosure to the precise form disclosed, and modifications and variations are possible in light of the above teachings or may be acquired from this disclosure. The implementations were chosen and described in order to explain the principals of the disclosure and its practical application to enable one skilled in the art to utilize the various implementations and with various modifications as are suited to the particular use contemplated. Other substitutions, modifications, changes, and omissions may be made in the design, operating conditions and implementation of the implementations without departing from the scope of the present disclosure as expressed in the appended claims.

1. A system comprising:
one or more processing circuits configured to:
receive an input task related to a real-world system;
select one or more agents for an agent-based model simulation of the real-world system based on a semantic comparison between metadata for a plurality of candidate agents and the input task, each of the one or more agents selected representing an entity of the real-world system;
generate a plurality of outputs by executing the agent-based model simulation comprising the one or more agents selected, each output of the plurality of outputs corresponding to respective values for one or more simulation properties;
update a knowledge base for storing information related to the real-world system based on the plurality of outputs for the respective values of the one or more simulation properties; and
respond to the input task by prompting one or more language models with a prompt including the input task, the plurality of outputs for the respective values of the one or more simulation properties, and other information retrieved from the updated knowledge base,
wherein including the simulation results from the agent-based model simulation improves the accuracy of the one or more language models.

2. The system of claim 1, wherein the one or more processing circuits are further configured to:
determine an amount of computational resources to be used to execute the agent-based model simulation based on the one or more agents selected; and
allocate the amount of the computational resources to perform the agent-based model simulation.

3. The system of claim 2, wherein:
the amount of the computational resources includes an amount of graphics processing units, central processing units, and field programmable gate array devices; and
the one or more processing circuits are configured to allocate the amount of graphics processing units, central processing units, and field programmable gate array devices.

4. The system of claim 2, wherein the one or more processing circuits are configured to determine the amount of the computational resources according to an objective function comprising at least one of a cost to execute the agent-based model simulation or a time required to execute the agent-based model simulation.

5. The system of claim 1, wherein the one or more processing circuits are further configured to adjust values for the one or more simulation properties for another agent-based model simulation based on the plurality of outputs.

6. The system of claim 5, wherein the one or more processing circuits are configured to adjust the values for the one or more simulation properties using a Monte Carlo tree search algorithm.

7. The system of claim 1, wherein the one or more processing circuits are further configured to determine whether the plurality of outputs conflict with the knowledge base by comparing a first trend from the plurality of outputs with a second trend indicated in the knowledge base.

8. The system of claim 7, wherein the one or more processing circuits are further configured to rerun the agent-based model simulation with updated values for the one or more simulation properties in response to determining the plurality of outputs conflict with the knowledge base.

9. The system of claim 1, wherein the one or more processing circuits are further configured to update the agent-based model simulation based on current information from the real-world system.

10. The system of claim 1, wherein the one or more processing circuits are further configured to store a log of updates to the agent-based model simulation.

11. The system of claim 1, wherein the one or more processing circuits are further configured to:
generate a second agent-based model simulation by selecting one or more alternative agents; and
determine whether the plurality of outputs and a plurality of second outputs from the second agent-based model simulation conflict.

12. The system of claim 1, wherein the one or more processing circuits are further configured to identify causal relationships between at least one of the plurality of outputs and the respective values of the one or more simulation properties.

13. The system of claim 1, wherein the metadata for a respective agent of the plurality of candidate agents comprises at least one of:
a name of the respective agent;
a description of the respective agent;
a description of the entity represented by the respective agent; or
a description of a set of rules followed by the respective agent within the agent-based model simulation.

14. The system of claim 1, wherein the one or more simulation properties comprise at least one of:
a parameter for a rule of an agent of the one or more agents selected;
a number of agents included in the agent-based model simulation; or
an initial condition of the agent-based model simulation.

15. A system comprising:
one or more processing circuits configured to operate an artificial intelligence-based agent for responding to tasks using a knowledge base for storing information related to a real-world system, the artificial intelligence-based agent configured to:
receive an inbound task related to the real-world system;
generate an agent-based model simulation of the real-world system by selecting a plurality of model agents based on a semantic comparison between metadata for a plurality of candidate agents and text related to the inbound task, each of the plurality of model agents selected representing an entity of the real-world system;
execute the agent-based model simulation to generate a first output;
adjust one or more properties of the agent-based model simulation based on the inbound task and the first output;
add, to the knowledge base, a summary of the first output and a second output of the adjusted agent-based simulation; and
respond to the inbound task by prompting one or more language models with a prompt including the inbound task, the plurality of outputs for the respective values of the one or more simulation properties, and other information retrieved from the updated knowledge base,
wherein including the simulation results from the agent-based model simulation improves the accuracy of the one or more language models.

16. The system of claim 15, wherein the artificial intelligence-based agent is further configured to allocate an amount of computational resources to be used to execute the agent-based model simulation according to an objective function comprising at least one of a cost to execute the agent-based model simulation or a time required to execute the agent-based model simulation, wherein the computational resources comprise at least one of graphics processing units, central processing units, or field programmable gate array devices.

17. The system of claim 15, wherein the artificial intelligence-based agent is further configured to:
determine whether the first output or the second output conflict with the knowledge base by comparing a first trend generated using at least the first output and the second output with a second trend indicated in the knowledge base; and
responsive to a determination that the first output or the second output conflict with the knowledge base, rerun the agent-based model simulation with updated values for the one or more properties.

18. The system of claim 15, wherein the artificial intelligence-based agent is further configured to update the agent-based model simulation based on current information from a real-world system represented by the agent-based model simulation.

19. The system of claim 15, wherein the automated action comprises at least one of:
update a user interface with a recommendation based on the summary, the recommendation determined to cause a real-world system represented by the agent-based model simulation to exhibit behavior observed in the agent-based model simulation;
generate an electronic mail communicating a recommendation based on the summary, the recommendation determined to cause the real-world system represented by the agent-based model simulation to exhibit behavior observed in the agent-based model simulation; and
generate an input to an application interface based on the summary, the input configured to cause the real-world system represented by the agent-based model simulation to exhibit behavior observed in the agent-based model simulation.

20. A method comprising:
receiving, by one or more processors, an input task related to a real-world system;
selecting, by the one or more processors, one or more agents for an agent-based model simulation of the real-world system based on a semantic comparison between metadata for a plurality of candidate agents and the input task, each of the one or more agents selected representing an entity of the real-world system;
generating, by the one or more processors, a plurality of outputs by executing the agent-based model simulation comprising the one or more agents selected, each output of the plurality of outputs corresponding to respective values for one or more simulation properties;
updating, by the one or more processors, a knowledge base for storing information related to the real-world system with a summary of the plurality of outputs for the respective values of the one or more simulation properties; and
responding, by the one or more processors, to the input task by prompting one or more language models with a prompt including the input task, the plurality of outputs for the respective values of the one or more simulation properties, and other information retrieved from the updated knowledge base,
wherein including the simulation results from the agent-based model simulation improves the accuracy of the one or more language models.
